(19) United States
(12) Patent Application Publication
(10) Pub. No.: US 2014/0017762 A1
(43) Pub. Date: Jan. 16, 2014

(54) NETWORK CONJUGATED POLYMERS WITH ENHANCED SOLUBILITY

(71) Applicant: Cuihua Xue, Irvine, CA (US)

(72) Inventor: Cuihua Xue, Irvine, CA (US)

(73) Assignee: Hitachi Chemical Research Center, Inc., Irvine, CA (US)

(21) Appl. No.: 14/007,753

(22) PCT Filed: Mar. 28, 2012
(86) PCT No.: PCT/US12/00174

§ 371 Date: Sep. 26, 2013

Related U.S. Application Data
(60) Provisional application No. 61/468,406, filed on Mar. 28, 2011.

(51) Int. Cl. H01L 51/00

(52) U.S. Cl. CPC H01L 51/0043
USPC 435/180; 528/9; 528/205; 525/54.2; 525/54.1; 525/417

(57) ABSTRACT

Cross-linked, conjugated organic semiconducting polymer networks that combine improved solubility with improved electrical and/or optical properties in one package have been developed. New materials that combine advantages of good charge-carrier mobility organic materials and conjugated polymer networks as well as fairly good solubility in common organic solvents, into one package and thus offers a general and powerful platform suitable for use in numerous applications.

### FIELD

The present disclosure relates to polymeric compositions, uses and related methods.

### BACKGROUND

In this specification where a document, act or item of knowledge is referred to or discussed, this reference or discussion is not an admission that the document, act or item of knowledge or any combination thereof was at the priority date, publicly available, known to the public, part of common general knowledge, or otherwise constitutes prior art under the applicable statutory provisions; or is known to be relevant to an attempt to solve any problem with which this specification is concerned.

Conjugated polymers as semiconducting organic materials have been the subject of intense interest for their applications in many areas, such as photovoltaic cells, organic light-emitting diodes, field-effect transistors, organic semiconductors, electronic optical sensors and other opto-electronic devices, and the like.

One drawback for these conjugated polymers is that they generally display a lower charge carrier mobility than, for example, inorganic semiconducting materials. The charge carrier mobility in these types of polymers is usually limited by disorder effects, which prevents efficient inter-chain communication and leads to polymers with one dimensional electronic properties, and thus, lower charge carrier mobility.

Conjugated polymer networks, on the other hand, have been proven to display significantly enhanced charge-carrier mobility. Conjugated polymer networks are polymeric systems that comprise a relatively high level of inter-chain communication. However, the use of such conjugated polymer networks has been limited due to their generally poor solubilities in organic or aqueous media, which leads to difficulties in making, handling and processing these materials. To maximize the industrial application of such conjugated polymer networks with increased efficiency of inter-chain communication, it is desirable to make conjugated polymer networks with improved solubility.

Thus, there is a need for cross-linked, conjugated polymer networks with improved solubility that are easily made, handled and processed.

While certain aspects of conventional technologies have been discussed to facilitate disclosure of the invention, Applicants in no way disclaim these technical aspects, and it is contemplated that the claimed invention may encompass or include one or more of the conventional technical aspects discussed herein.

### SUMMARY

According to certain aspects of the invention, cross-linked, conjugated organic semiconducting polymer networks that combine improved solubility with improved electrical and/or optical properties in one package have been developed.

According to certain aspects, the invention provides new materials that combine advantages of good charge-carrier mobility organic materials and conjugated polymer networks as well as fairly good solubility in common organic solvents, into one package and thus offers a general and powerful platform suitable for use in numerous applications. Materials of the present invention may also feature near infrared (NIR) optical properties.

According to certain aspects of the invention, a series of conjugated polymer networks have been developed by a post-crosslink approach. The conjugated polymer networks are made from highly functionalized polymeric precursor starting materials which can be cross-linked using an appropriate cross-linker or using appropriate reactions. The size of the networks can also be adjusted, for example, by controlling the ratio of the cross-linker to polymer precursor starting materials. A cross-linked polymeric network of the general formula is shown below:

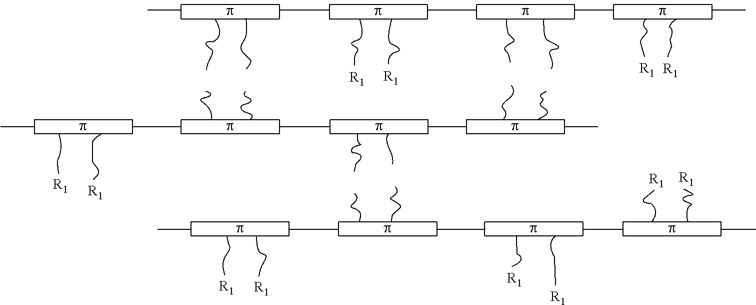

wherein R₁ can be any functional group, such as, without limitation, H, alkyl, alkene, alkyne, OH, Br, Cl, I, F, SH, COOH, NH₂, NR₃, azide, SO₃Na, CHO, maleimide, NHS ester, and any heterocyclic compounds that can form a metal complex or nano-particle other applicable functional group, such as a carbohydrate, a protein, DNA, an antibody, an antigen, an enzyme or a bacteria.

According to one aspect, the present invention provides a cross-linked polymeric network made from polymeric precursor starting materials of the general formulas shown below:

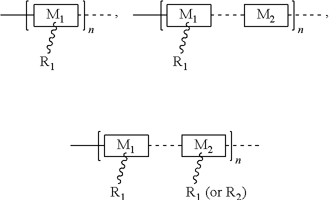

wherein:

M₁=a substituted or un-substituted conjugated monomer, conjugated block oligomer, alkene, or alkyne;

M₂=a substituted or un-substituted monomer, a conjugated block oligomer, an alkene, or an alkyne, each with or without side chains;

[symbol] =a oligo- or poly-ethylene glycol, an alkyl chain with or without branches, or an optionally substituted conjugated chain;

[symbol] =a single bond, a double bond. or a triple bond:

n=an integer greater than 1; and

R₁ and R₂ can be any functional group, such as, without limitation, H, alkyl, alkene, alkyne, OH, Br, Cl, I, F, SH, COOH, NH₂, NR₃, azide, SO₃Na, CHO, maleimide, NHS ester, or any heterocyclic compounds that can form a metal complex or nano-particle other applicable functional group, such as a carbohydrate, a protein, DNA, an antibody, an antigen, an enzyme or a bacteria; and wherein:

Monomer M₁ and M₂ can have, without limitation, zero, one or more than one side chain

[symbol]

the side chain [symbol] in monomers M₁ and M₂, without limitation, can be the same or different, or one side chain has at least one reactive group and another side chain has no reactive group;

R₁ and R₂, without limitation, can be the same or different, or one is functional group and another is non-functional group, wherein a non-functional group being characterized by a lack of reaction with another molecule of the polymer

According to one aspect, the present invention provides a polymeric precursor material comprising: a copolymer of:

a first monomer (1), (2), (3) (4), (5), (6), (7), (8), (9), (10), (11), (12), (13), (14) or (15); and

a second monomer (16), (17), (18), (19), (20), (21), (22), (23), (24), (25), (26) or (27);

wherein:

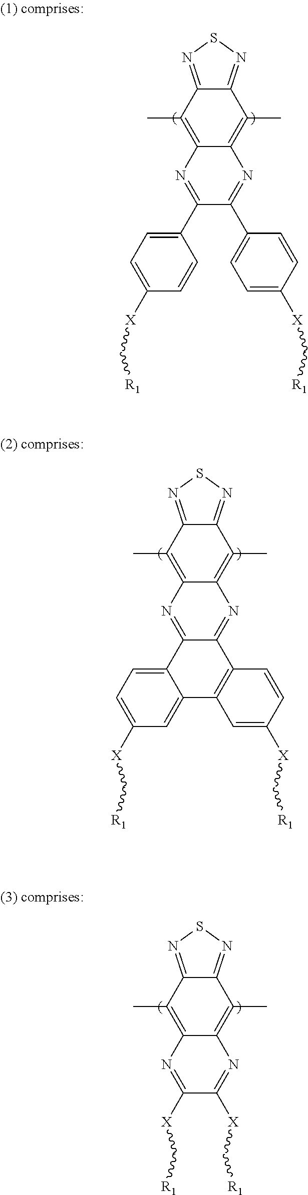

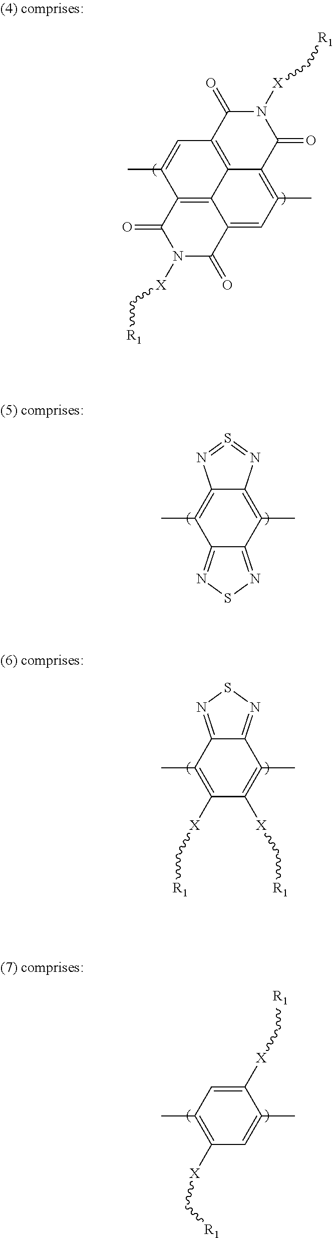

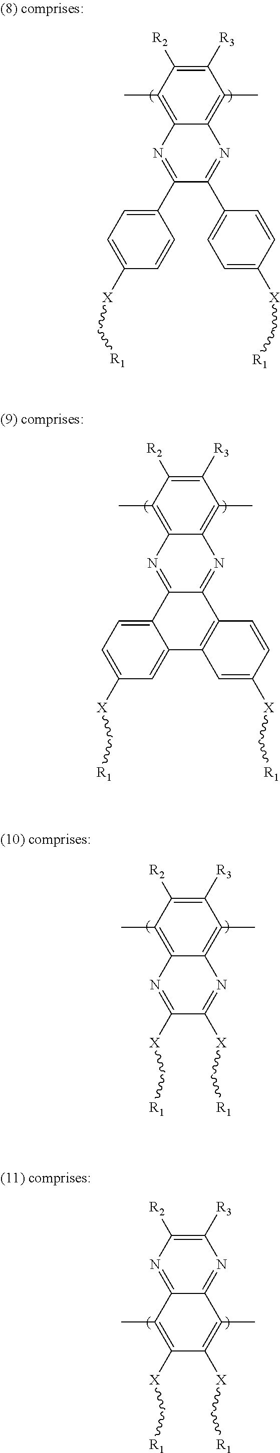

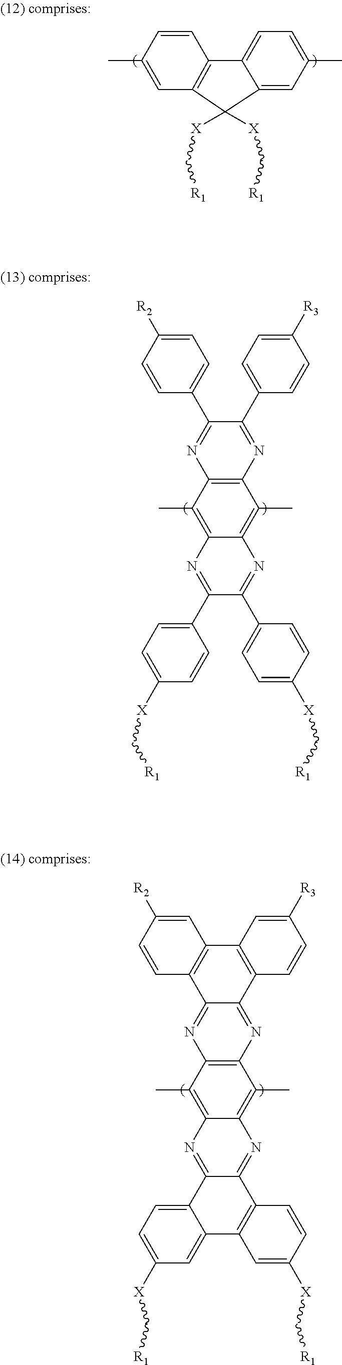

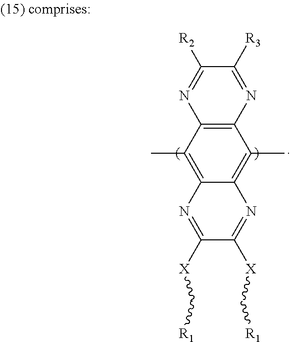

wherein
X=H, C, O, N, S, P, Si, or B;
[symbol] =H, oligo- or poly-ethylene glycol, alkyl chain with or without branches, an optionally substituted conjugated chain;
R₂ and R₃=H or X [symbol] R₁;
R₁=H, alkyl, alkene, alkyne, OH, Br, Cl, I, F, SH, COOH, NH₂, NR₃, azide, SO₃Na, CHO, maleimide, HNS ester, or any heterocyclic compounds that can form a metal complex or nano-particle or other applicable functional group, such as a carbohydrate, a protein, DNA, an antibody, an antigen, an enzyme or a bacteria wherein

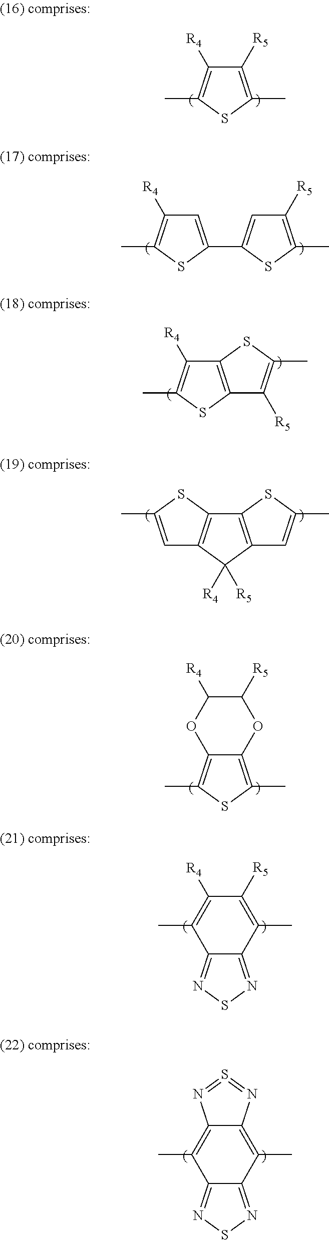

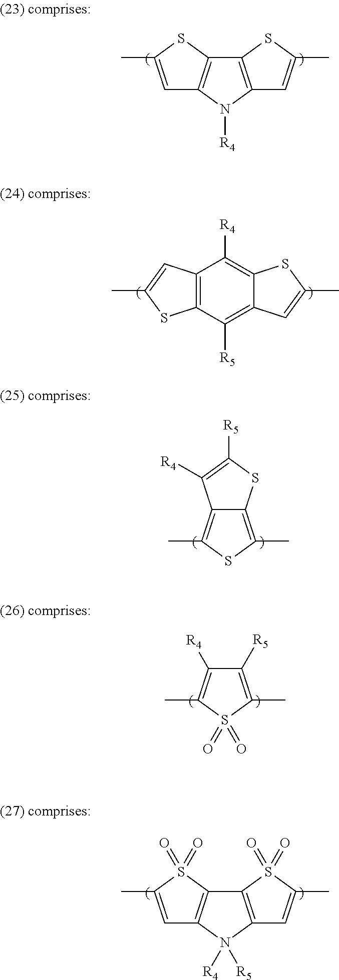

wherein
X=C, O, CO, N, S, P, Si, or B;
[symbol] =oligo- or poly-ethylene glycol, an alkyl chain with or without branches, or an optionally substituted conjugated chain;
R₄ and R₅=H or X [symbol] R₁; and
R₁=H, alkyl, alkene, alkyne, OH, Br, Cl, I, F, SH, COOH, NH₂, NR₃, azide, SO₃Na, CHO, maleimide, or HNS ester, or an heterocyclic compounds that can form a metal complex or nano-particle or other applicable functional group, such as a carbohydrate, a protein, DNA, an antibody, an antigen, an enzyme or a bacteria.

According to another aspect, the present invention provides a polymeric precursor material comprising: a copolymer of:

a first monomer (28), (29), (30) (31), (32), (33), (34), (35), (36), (37) or (38); and

a second monomer (39), (40), (41), (42), (43), (44), (45), (46), (47), (48) (49), (50), (51), (52, (53) or (54);

wherein:

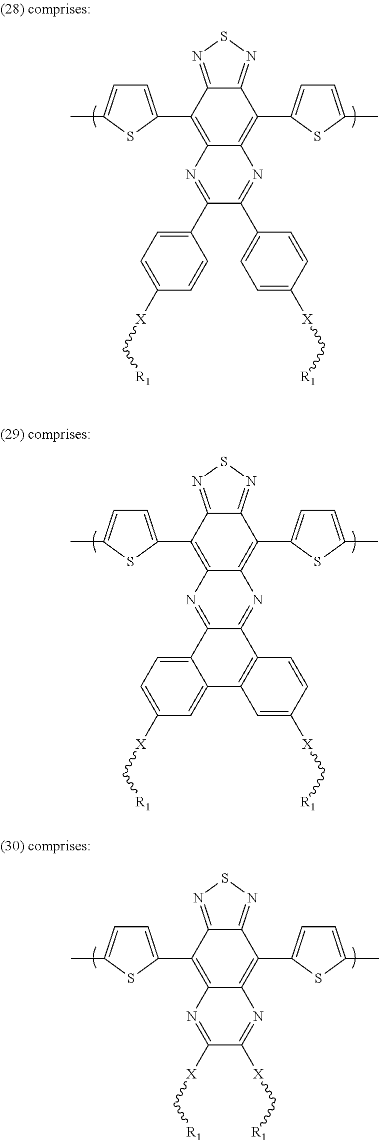

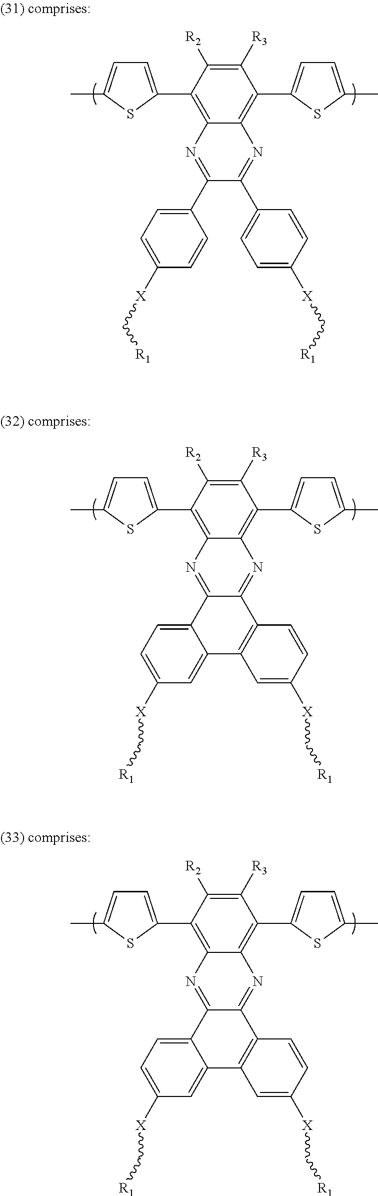

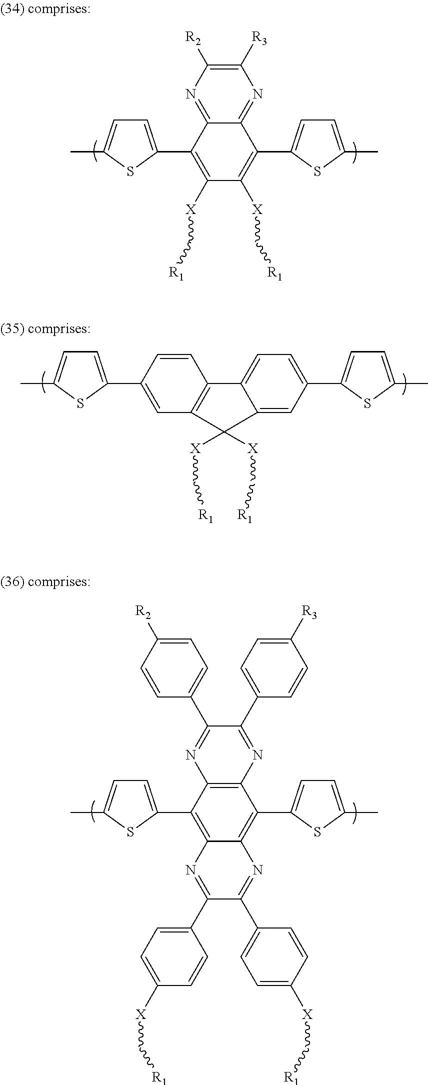

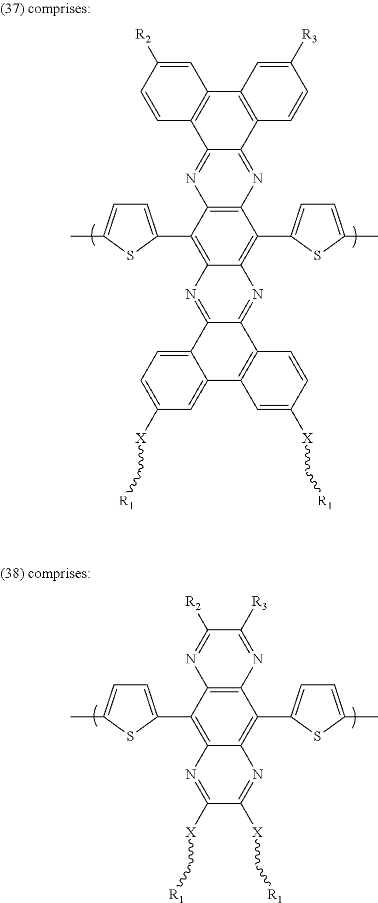

wherein
X=H, C, O, N, S, P, Si, B;
[symbol] =H, oligo- or poly-ethylene glycol, alkyl chain with or without branches, or an optionally substituted conjugated chain;
R₂ and R₃=H or X [symbol] R₁;
R₁=H, alkyl, alkene, alkyne, OH, Br, Cl, I, F, SH, COON, NH₂, NR₃, azide, SO₃Na, CHO, maleimide, or HNS ester, or an heterocyclic compounds that can form a metal complex or nano-particle or other applicable functional group, such as a carbohydrate, a protein, DNA, an antibody, an antigen, an enzyme or a bacteria and

wherein:

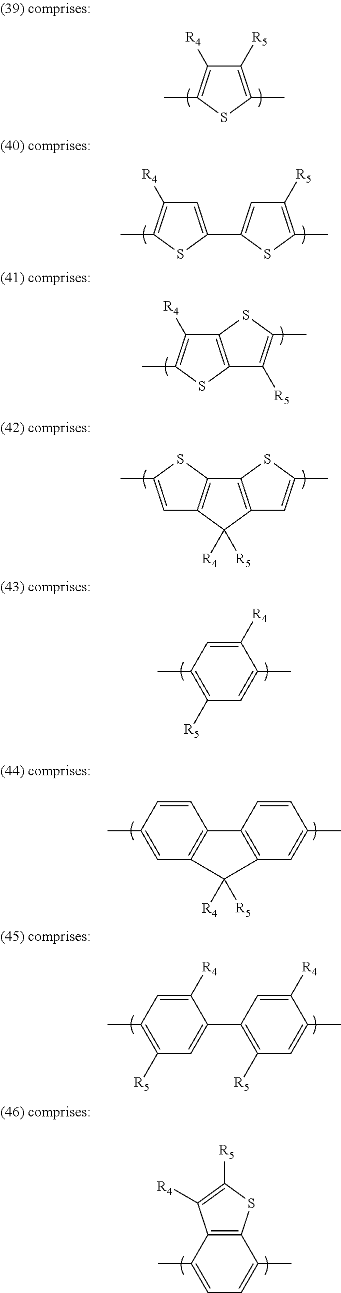

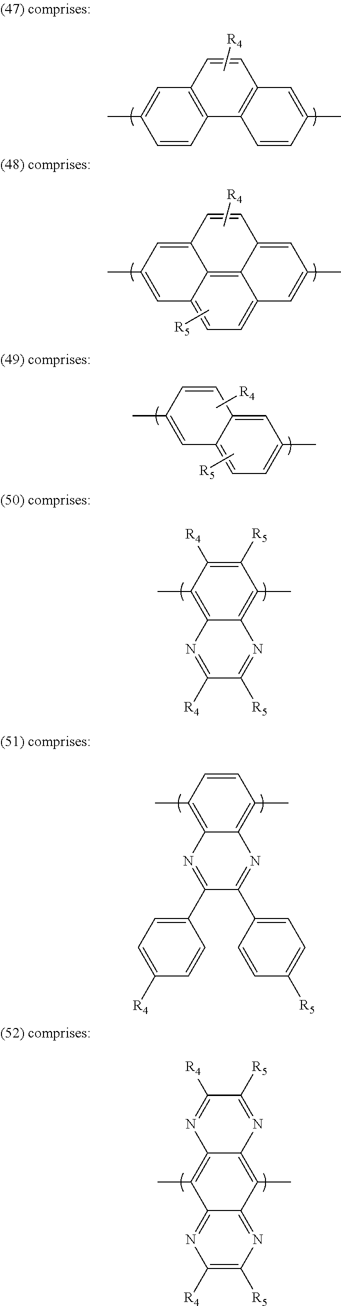

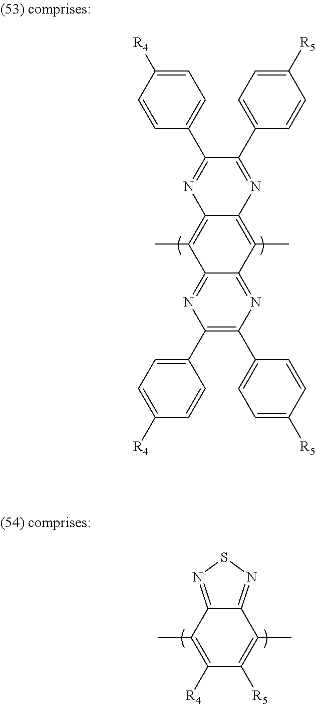

wherein
X=C, O, CO, N, S, P, Si, or B;
[symbol] =oligo- or poly-ethylene glycol, alkyl chain with or without branches, or an optionally substituted conjugated chain;
R₄ and R₅=H or X [symbol] R₁;
R₁=H, alkyl, alkene, alkyne, OH, Br, Cl, I, F, SH, COOH, NH₂, NR₃, azide, SO₃Na, CHO, maleimide, or HNS ester, or any heterocyclic compounds that can form a metal complex or nano-particle or other applicable functional group, such as a carbohydrate, a protein, DNA, an antibody, an antigen, an enzyme or a bacteria.

According to yet another aspect, the present invention provides a polymeric precursor material comprising: a copolymer of:

a first monomer (1), (2), (3) (4), (5), (6), (7), (8), (9), (10), (11), (12), (13), (14) or (15) as described above; and

a second monomer (39), (40), (41), (42), (43), (44), (45), (46), (47), (48) (49), (50), (51), (52, (53) or (54) as described above.

According to yet another aspect, the present invention provides a polymeric precursor material comprising: a copolymer of:

a first monomer (28), (29), (30) (31), (32), (33), (34), (35), (36), (37) or (38) as described above; and

a second monomer (16), (17), (18), (19), (20), (21), (22), (23), (24), (25), (26) or (27) as described above.

According to a further aspect, the present invention provides a polymeric precursor material comprising: a copolymer of:

a first monomer (1), (2), (3) (4), (5), (6), (7), (8), (9), (10), (11), (12), (13), (14) or (15) as described above; and

a second monomer (16), (17), (18), (19), (20), (21), (22), (23), (24), (25), (26) or (27) as described above; and further comprising:

a third monomer (39), (40), (41), (42), (43), (44), (45), (46), (47), (48) (49), (50), (51), (52, (53) or (54) as described above.

According to a further aspect, the present invention provides a polymeric precursor material comprising: a copolymer of:

a first monomer (28), (29), (30) (31), (32), (33), (34), (35), (36), (37) or (38) as described above; and

a second monomer (16), (17), (18), (19), (20), (21), (22), (23), (24), (25), (26) or (27) as described above; and further comprising:

a third monomer (39), (40), (41), (42), (43), (44), (45), (46), (47), (48), (49), (50), (51), (52, (53) or (54) as described above.

According to yet a further aspect, the present invention provides a polymeric precursor material comprising one of the monomers (1)-(54) as described above. In other words, the present invention provides a polymeric precursor material comprising a self-polymerization product of one of the monomers (1)-(54).

The present invention may address one or more of the problems and deficiencies of the prior art discussed above. However, it is contemplated that the invention may prove useful in addressing other problems and deficiencies, or provide benefits and advantages, in a number of technical areas. Therefore the claimed invention should not necessarily be construed as being limited to addressing any of the particular problems or deficiencies discussed herein.

### BRIEF DESCRIPTION OF THE DRAWINGS

These and other feature of this invention will now be described with reference to the drawings of certain embodiments which are intended to illustrate and not to limit the invention.

FIG. 1 shows an absorption spectra of a polymeric precursor material formed according to the principles of the present invention.

FIG. 2 shows an absorption spectra of another polymeric precursor material formed according to the principles of the present invention.

FIG. 3 shows superimposed absorption spectra of a polymeric precursor material and a cross-linked polymeric network material formed according to the principles of the present invention.

FIG. 4 shows SEM images of a polymeric precursor material and a cross-linked polymeric network material formed according to the principles of the present invention; FIG. 4A shows the SEM image of the polymeric precursor material; FIG. 4B shows the SEM image of a cross-linked polymeric network.

FIG. 5 shows an AFM image of a polymeric precursor material formed in according to the principles of the present invention.

FIG. 6 shows an AFM image of a network polymeric material formed in according to the principles of the present invention.

FIG. 7 shows superimposed absorption spectra of a polymeric precursor material and a cross-linked polymeric network material formed according to the principles of the present invention.

### DETAILED DESCRIPTION OF THE PREFERRED EMBODIMENTS

Further aspects, features and advantages of this invention will become apparent from the detailed description which follows.

Polymers or polymer precursors of the present invention can be composed or synthesized according to a number of alternatives. For example, polymers can be formed by co-polymerizing one of the monomers from Table 1 and one of the monomers from Table 2. Also, polymers can be formed by co-polymerizing one of the monomers from Table 1, one of the monomers from Table 2, and one of the monomers from Table 4. Polymer precursors can also be synthesized by co-polymerizing one of the monomers from Table 3, and one of the monomers from Table 2 and/or one of the monomers from Table 4. Alternatively, polymer precursors can be synthesized by self-polymerizing a monomer from Table 1, Table 2, Table 3 or Table 4.

TABLE 1

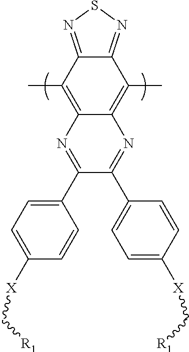

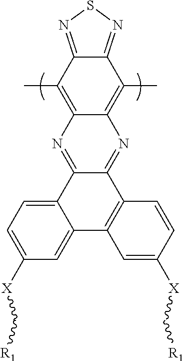

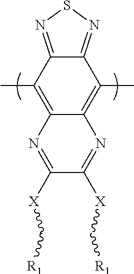

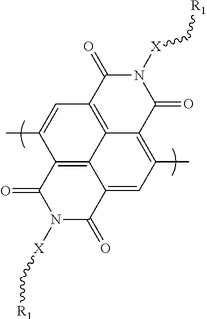

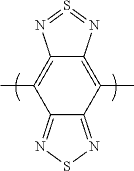

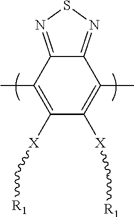

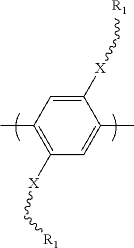

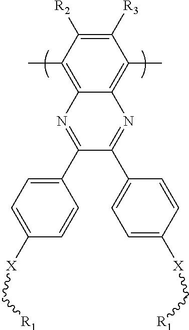

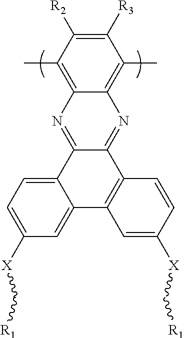

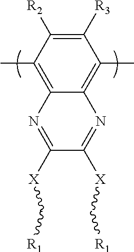

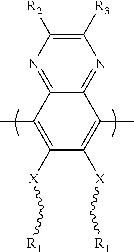

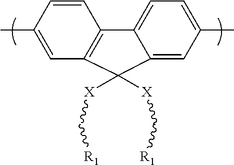

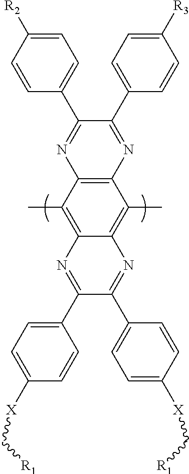

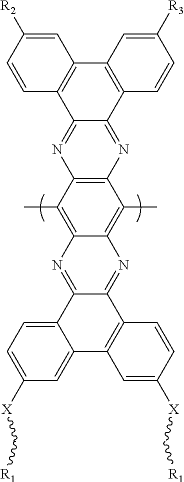

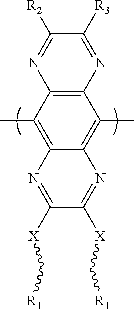

X = C, O, CO, N, S, P, Si, or B [symbol]
= H, oligo- or poly- ethylene glycol, an alkyl chain with or without branches, or an optionally substituted conjugated chain
R₁ = H, alkyl, alkene, alkyne, OH, Br, Cl, I, F, SH, COOH, NH₂, NR₃, azide, SO₃Na, CHO, maleimide, or NHS ester, or any heterocyclic compounds that can form a metal complex or nano-particle or other applicable functional group, such as a carbohydrate, a protein, DNA, an antibody, an antigen, an enzyme or a bacteria
R₂ and R₃ = H or X [symbol] R₁

TABLE 2

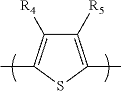

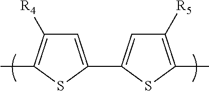

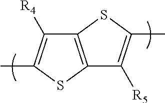

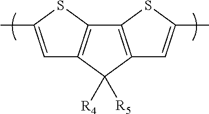

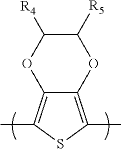

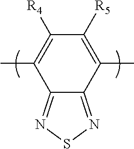

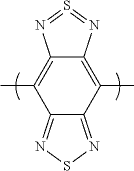

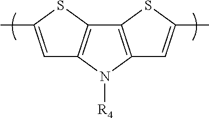

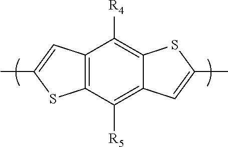

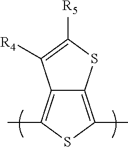

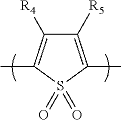

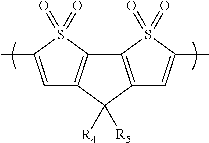

R₄ and R₅ = H or X [symbol] R₁, or one if H and the other is X [symbol] R₁
X = C, O, CO, N, S, P, Si, or B [symbol]
= oligo- or poly- ethylene glycol, an alkyl chain with or without branches, or an optionally substituted conjugated chain
R₁ = H, alkyl, alkene, alkyne, OH, Br, Cl, I, F, SH, COOH, NH₂, NR₃, azide, SO₃Na, CHO, maleimide, or NHS ester, or any heterocyclic compounds that can form a metal complex or nano-particle or other applicable functional group, such as a carbohydrate, a protein, DNA, an antibody, an antigen, an enzyme or a bacteria

TABLE 3

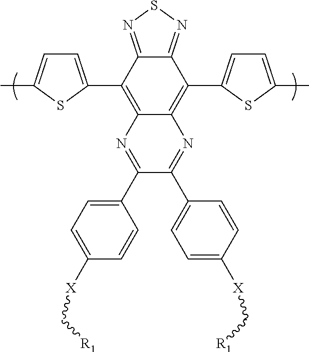

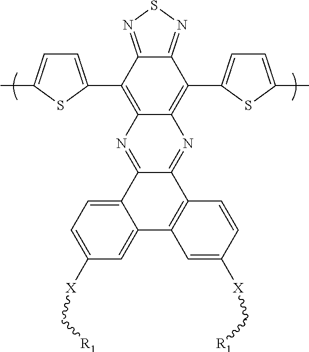

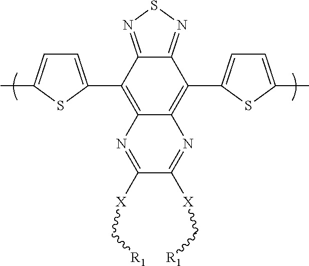

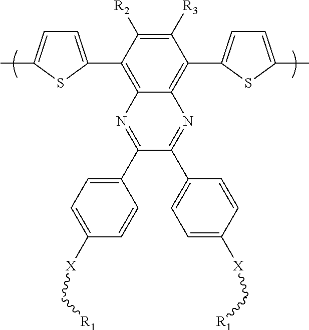

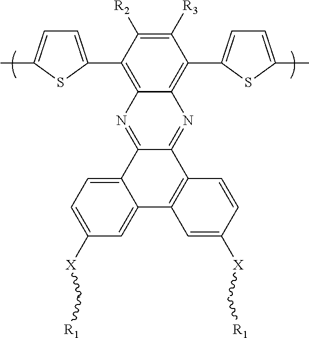

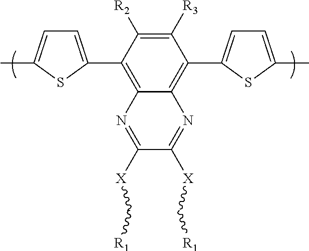

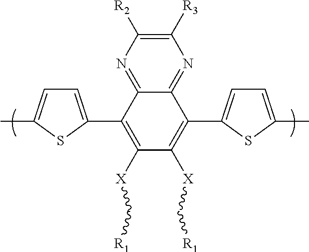

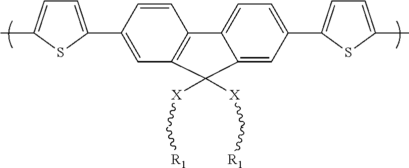

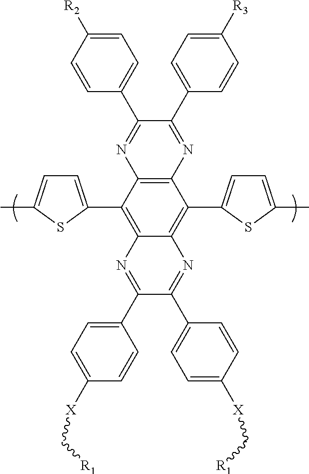

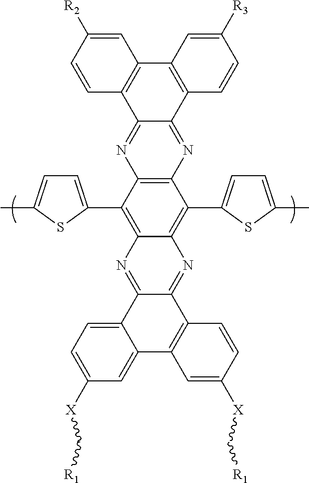

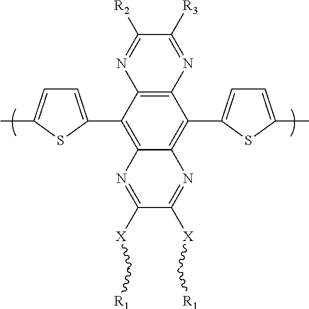

X = C, O, CO, N, S, P, Si, or B [symbol]
= H, oligo- or poly- ethylene glycol, an alkyl chain with or without branches, or an optionally substituted conjugated chain
R₁ = H, alkyl, alkene, alkyne, OH, Br, Cl, I, F, SH, COOH, NH₂, NR₃, azide, SO₃Na, CHO, maleimide, or NHS ester, or any heterocyclic compounds that can form a metal complex or nano-particle or other applicable functional group, such as a carbohydrate, a protein, DNA, an antibody, an antigen, an enzyme or a bacteria
R₂ and R₃ = H or X [symbol] R₁

TABLE 4

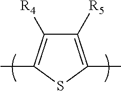

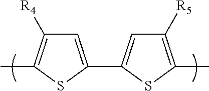

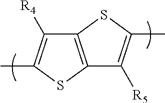

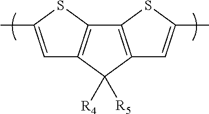

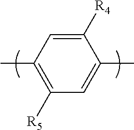

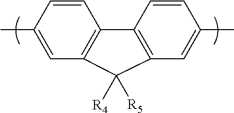

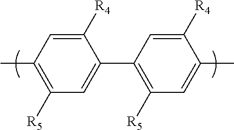

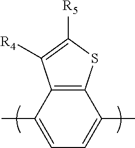

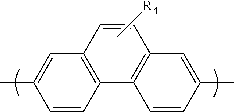

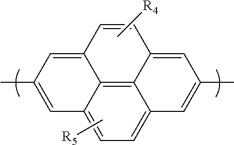

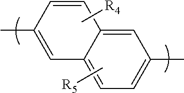

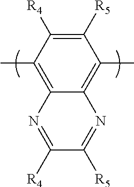

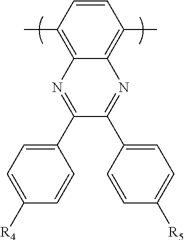

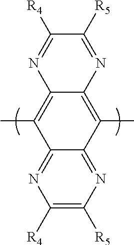

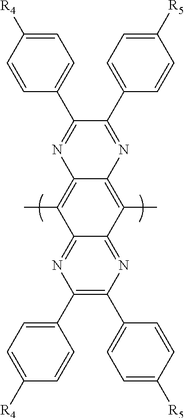

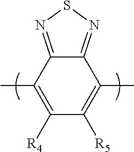

R₄ and R₅ = H or X [symbol] R₁, or one if H and the other is X [symbol] R₁
X = C, O, CO, N, S, P, Si, or B [symbol]
= oligo- or poly- ethylene glycol, an alkyl chain with or without branches, or an optionally substituted conjugated chain
R₁ = H, alkyl, alkene, alkyne, OH, Br, Cl, I, F, SH, COOH, NH₂, NR₃, azide, SO₃Na, CHO, maleimide, or NHS ester, or any heterocyclic compounds that can form a metal complex or nano-particle or other applicable functional group, such as a carbohydrate, a protein, DNA, an antibody, an antigen, an enzyme or a bacteria

Representative polymer precursors in accordance with the present invention are showed in Table 5. The polymer precursors shown in Table 5 are made by co-polymerization or self-polymerization of monomers (1), (16), (28) and/or (43) as described above. The polymer precursors have good solubility in a number of common organic solvents and/or in water. Such solvents are, without limitation, methylene chloride (CH₂Cl₂), chloroform (CHCl₃), tetrahydrofuran (THF), benzene, toluene and chlorobenzene. If the polymer precursors are properly modified, the polymer precursors can have solubility in water. For example, the polymer precursors described above can be functionalized by attaching any suitable functional groups, such as bio-molecules, to its reactive sites.

Thus, an advantage of the conjugated polymer networks synthesized from the polymer precursor materials described herein is that they can be made soluble in water in their precursor state or after they have been functionalized. Examples of suitable molecules for functionalization may include, without limitation, carbohydrates, proteins, peptides, DNA, antibodies, antigens, enzymes and/or bacteria. The resulting conjugated polymer networks can be used in applications that require high hydrophilic properties or water solubility, such as medical detection, imaging, targeting, drug discovery and/or drug delivery. R₁ and/or R₂ can be further modified by other chemical or biological molecules to achieve specific applications in photovoltaic cells, organic light-emitting diodes, field-effect transistors, organic semiconductors, electronic optical sensors and other opto-electronic devices, and the like. The remaining functional groups along the polymer side chains in the network may also be further modified by other chemical or biological molecules to achieve desired specific applications.

Polymer precursor materials can be cross-linked to form the conjugated polymer networks in accordance with the present invention. For example, a representative conjugated polymer network in accordance with the present invention is shown in Table 6. The inventive conjugated polymer networks can be cross-linked by any suitable cross-linking agent, such as a di-functional cross-linking agent. The di-functional cross-linking agent can be any di-functional reagent that reacts with reactive groups R₁ and/or R₂ of the side chains of the polymer precursors. Examples of the cross-linking agents can be, without limitation, a dithio-containing C₁₋₁₅ alkyl chain such as 1,3-dithiopropane; a diamine-containing C₁₋₁₅ alkyl chain such as ethylenediamine; a di-carboxylic acid and its derivatives; a di-bromo containing C₁₋₁₅ alkyl chain; a di-azide, a di-alkyne containing C₁₋₁₅ alkyl chain. The alkyl chain and/or the di-functional moiety of the of the cross-linking agent can be with or without other branched side chains, such as substituted and/or un-substituted aryl and heterocyclic rings. The cross-linking agent may also be any multi-functional chemical reagent that reacts with the reactive groups R₁ and/or R₂ of the side chains of the polymer precursors. Such multi-functional chemical reagents include, without limitation, nano-particles and metal complexes. The inventive polymer networks also can be formed by cross-linking any of the inventive polymer precursor materials by any suitable chemical reactions directly between polymer precursor materials with different functional groups. Such reactions include, but are not limited to, click reactions, condensation reactions and substitution reactions. The cross-linking can be carried out in many common organic solvents such as, without limitation, CH₂Cl₂, CHCl₃, THF, benzene, toluene and chlorobenzene or in water, depending upon the networks desired. The size of the networks can be controlled by adjusting the ratio of the cross-linking agents or the number of the reactive groups along the side chains.

TABLE 5

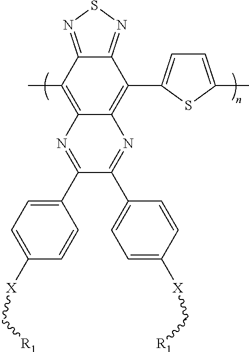

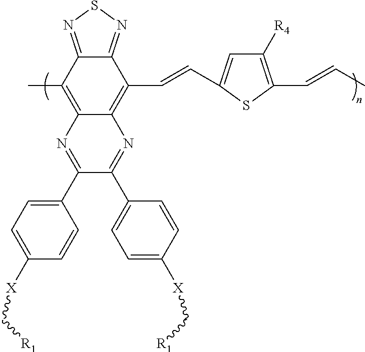

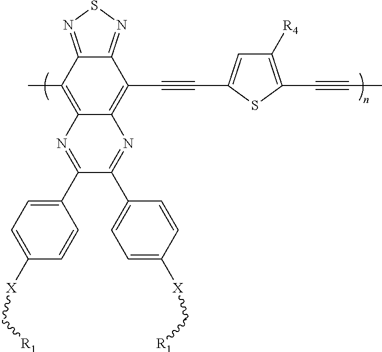

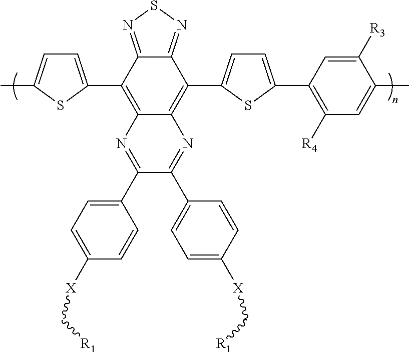

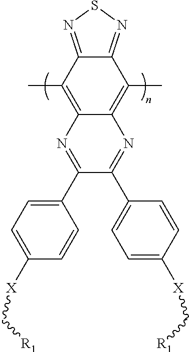

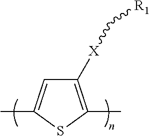

X = C, O, CO, N, S, P, Si, or B [symbol]
= H, oligo- or poly- ethylene glycol, an alkyl chain with or without branches, or an optionally substituted conjugated chain
R₁ = H, alkyl, alkene, alkyne, OH, Br, Cl, I, F, SH, COOH, NH₂, NR₃, azide, SO₃Na, CHO, maleimide, or NHS ester, or any heterocyclic compounds that can form a metal complex or nano-particle or other applicable functional group, such as a carbohydrate, a protein, DNA, an antibody, an antigen, an enzyme or a bacteria

The wavelength of energy absorbed by the polymers is around 700-1100 nm or above 1100 nm, and the absorption can be adjusted by adjusting the degree of polymerization.

TABLE 6

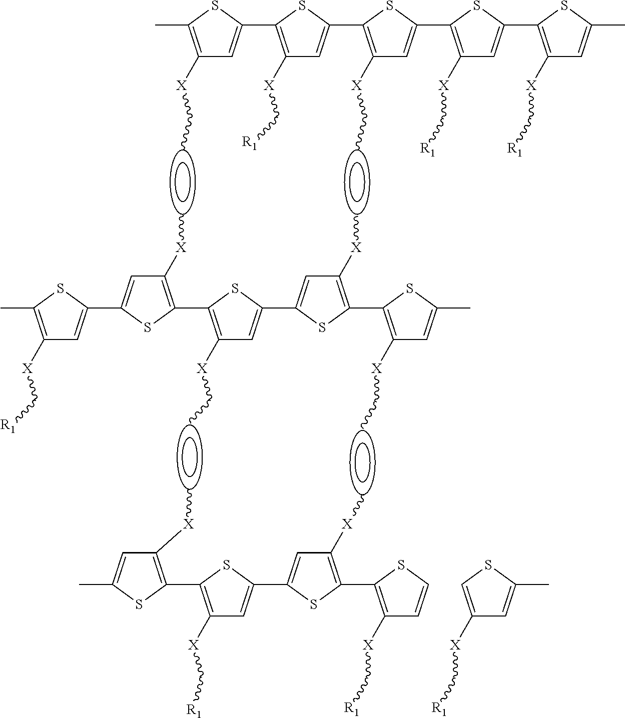

X = C, O, CO, N, S, P, Si, or B [symbol]
= oligo- or poly- ethylene glycol, an alkyl chain with or without branches, or an optionally substituted conjugated chain
R₁ = H, alkyl, alkene, alkyne, OH, Br, Cl, I, F, SH, COOH, NH₂, NR₃, azide, SO₃Na, CHO, maleimide, or NHS ester, or any heterocyclic compounds that can form a metal complex or nano-particle or other applicable functional group, such as a carbohydrate, a protein, DNA, an antibody, an antigen, an enzyme or a bacteria

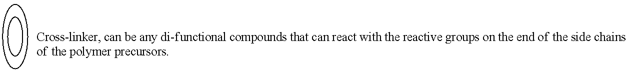

The concepts of the present invention will now be further described by reference to the following non-limiting examples of specific inventive polymer networks of the polymer precursors and exemplary techniques for their formation. It should be understood that additional polymers and additional techniques of formation are also comprehended by the present invention.

### EXAMPLE 1

### Synthesis of Polymer 1

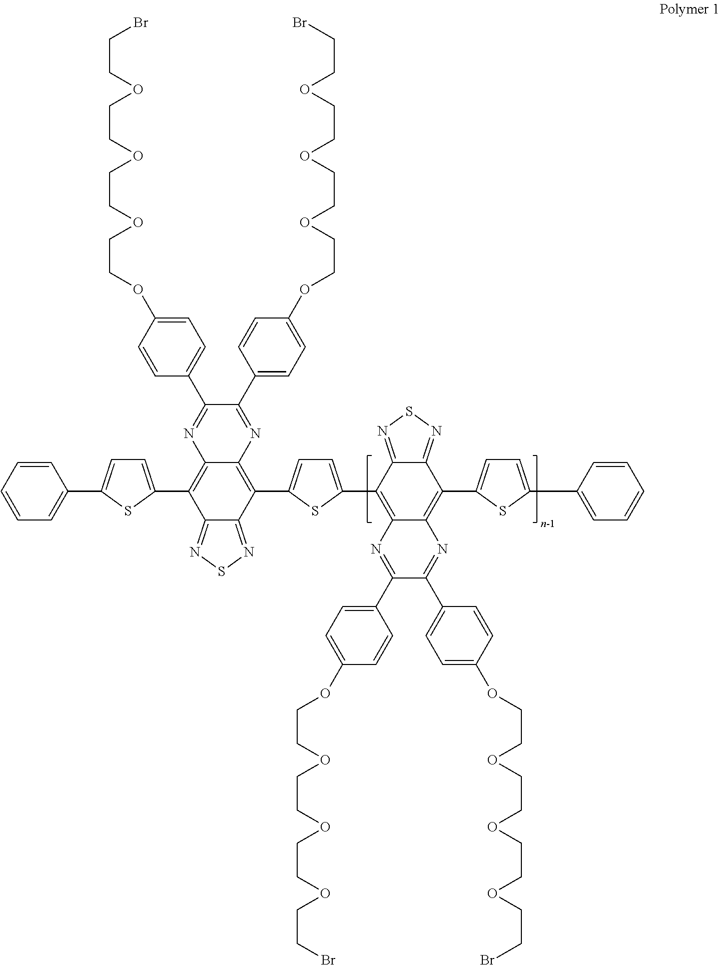

Scheme 1 below illustrates the synthesis of 4,7-dibromo-5,6-diamine-benzo[1,2,5]thiadiazole 4 starting from benzo[1,2,5]thiadiazole.

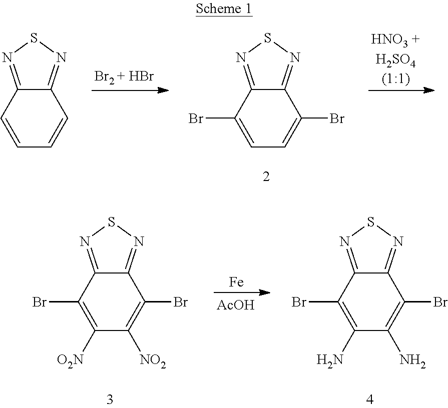

To a 500 mL three-necked round-bottomed flask were added benzothiadiazole (10.0 g, 73.4 mmol) and HBr (150 mL, 48%). A solution containing Br₂ (35.2 g, 220.3 mmol) in HBr (100 mL) was added dropwise very slowly. After the total addition of Br₂, the solution was heated at reflux for overnight. Precipitation of a dark orange solid was noted. The mixture was cooled to room temperature, and a sufficient amount of a saturated solution of NaHSO₃ was added to completely consume any excess Br₂. The mixture was filtered under vacuum and washed exhaustively with water and dried under vacuum to afford dibrominated product (2). ¹H Nuclear Magnetic Resonance (NMR) spectroscopy can be used to obtain structural information about the hydrogen molecules in a given molecule. ¹H NMR yielded the following results for product 2: (500 MHz, deuterated chloroform—CDCl₃): δ 7.75 (s, 2H) ppm.

4,7-dibromobenzo[1,2,5]thiadiazole 2 (40 g, 137 mmol) was added to a mixture of fuming sulphuric acid (200 ml) and fuming nitric acid (200 ml) in small portions at 0° C. and then the reaction mixture was stirred at room temperature for 72 hrs. After 72 hrs, the mixture was poured into ice-water, the solid was filtered and washed with water several times, then recrystallized in ethanol to give compound (3) as a pale yellow solid.

A mixture of 4,7-dibromo-5,6-dinitro-benzo[1,2,5]thiadiazole 3 (10 g, 26 mmol) and fine iron powder (10 g, 178 mmol) in acetic acid was stirred at 80° C. until compound (3) completely disappeared monitored by thin layer chromatography (TLC). The reaction mixture was cooled down to room temperature and then precipitated in 5% solution of NaOH. The solid was filtered and washed with water several times. Obtained filter cake was dissolved in hot EtOAc and then filtered to remove unreacted iron, the filtrate was evaporated to remove solvent on a rotary evaporator to give 4,7-dibromo-5,6-diamine-benzo[1,2,5] thiadiazole (4) as a yellow solid. ¹ H NMR (500 MHz, dimethylsulfoxide—DMSO): δ 3.31 (s, 4H) ppm.

Scheme 2 shows the synthesis of compound 6, 1,2-bis(4-(2-(2-(2-(2-bromoethoxy)ethoxy)ethoxy)ethoxy)phenyl)ethane-1,2-dione.

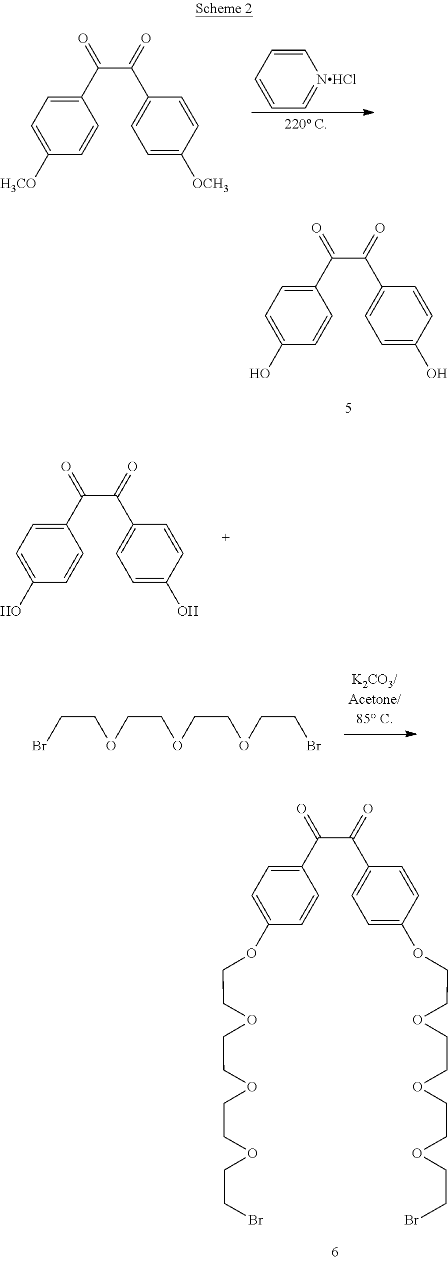

4,4′-Dimethoxy-benzil (5 g, 18.33 mmol) and pyridinium hydrochloride (12.8 g, 111 mmol) were heated at 220° C. until complete melting of the solid mixture. Heating was maintained for 1.5 hrs. After cooling down to 80° C., water (50 mL) was added dropwise to give a suspension which was filtered while hot. The collected solid was dissolved in ethyl acetate and the solution dried over MgSO₄.

After removal of solvent, obtained solid was simply re-crystallized to give compound 5, 1,2-bis(4-hydroxyphenyl)ethane-1,2-dione as a pale yellow solid (4.4 g, almost quantitative). ¹H NMR (500 MHz, DMSO): δ 10.8 (s, 2H), 7.71 (d, J=8.8 MHz, 4H), 6.90 (d, J=8.8 MHz, 4H) ppm.

1,2-bis(4-hydroxyphenyl)ethane-1,2-dione (2.6 g, 10.74 mmol) was dissolved in acetone and K₂CO₃ (5.9 g, 42.7 mmol) was added, then 80 mmol of 1-bromo-2-(2-(2-(2-bromoethoxy)ethoxy)ethoxy)ethane was added. The mixture was heated to 80° C. and stirred for 24 hrs. TLC check showed 1,2-bis(4-hydroxyphenyl)ethane-1,2-dione disappeared. Acetone was removed, and water was added, extracted by EtOAc, washed with brine, dried over MgSO₄. The solvent was removed and residue was purified by column chromatography to give 1,2-bis(4-(2-(2-(2-(2-bromoethoxy)ethoxy)ethoxy)ethoxy)phenyl)ethane-1,2-dione (6) as a pale yellow oil. ¹H NMR (500 MHz, CDCl₃): δ 7.94 (d, J=8.8 MHz, 4H), 6.99 (d, J=8.8 MHz, 4H), 4.21 (t, J=4.8 MHz, 4H), 3.88 (t, J=4.8 MHz, 4H), 3.80 (t, J=6.3 MHz, 4H), 3.78-3.66 (m, 16H), 3.46 (t, J=6.3 MHz, 4H) ppm.

Scheme 3 below shows the synthesis of Monomer 1, 4,9-dibromo-6,7-bis(4-(2-(2-(2-(2-bromoethoxy)ethoxy)ethoxy)ethoxy)phenyl)-[1,2,5]thiadiazolo[3,4-g]quinoxaline.

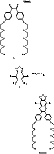 [SMILES: O=C(C(=O)c1ccc(OCCOCCOCCOCCBr)cc1)c1ccc(OCCOCCOCCOCCBr)cc1 ; Nc1c(N)c(Br)c2nsnc2c1Br ; BrCCOCCOCCOCCOc1ccc(-c2nc3c(Br)c4nsnc4c(Br)c3nc2-c2ccc(OCCOCCOCCOCCBr)cc2)cc1]

4,7-dibromo-5,6-diamine-benzo[1,2,5]thiadiazole 4 (0.6 g, 1.23 mmol) and 1,2-bis(4-(2-(2-(2-(2-bromoethoxy)ethoxy)ethoxy)ethoxy)phenyl)ethane-1,2-dione (6) (0.89 g, 1.23 mmol) were placed in a reaction flask, and AcOH was added. The reaction mixture was heated to 125° C. and stirred for 3.5 hrs. TLC check showed both compound 4 and 6 disappeared. The mixture was cooled down to room temperature and poured into water, and then extracted by EtOAc, washed with brine, dried over MgSO₄. The residue was purified by column chromatography to give Monomer 1,4,9-dibromo-6,7-bis(4-(2-(2-(2-(2-bromoethoxy)ethoxy)ethoxy)ethoxy)phenyl)-[1,2,5]thiadiazolo[3,4-g]quinoxaline as an orange sticky oil. ¹H NMR (500 MHz, CDCl₃): δ 7.75 (d, J=8.8 MHz, 4H), 6.94 (d, J=8.8 MHz, 4H), 4.20 (t, J=4.8 MHz, 4H), 3.90 (t, J=4.8 MHz, 4H), 3.82 (t, J=6.3 MHz, 4H), 3.76-3.69 (m, 16H), 3.47 (t, J=6.3 MHz, 4H) ppm.

Scheme 4 below shows the co-polymerization of Monomer 1 and 2,5-bis(tributylstannyl)thiophene to produce Polymer 1.

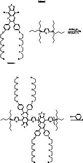

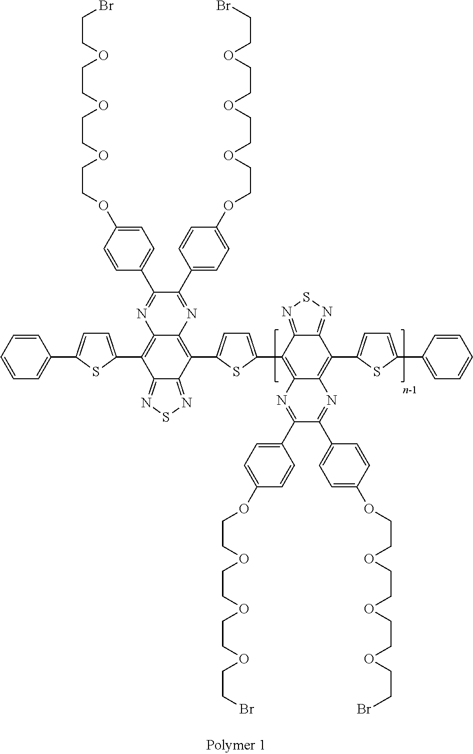

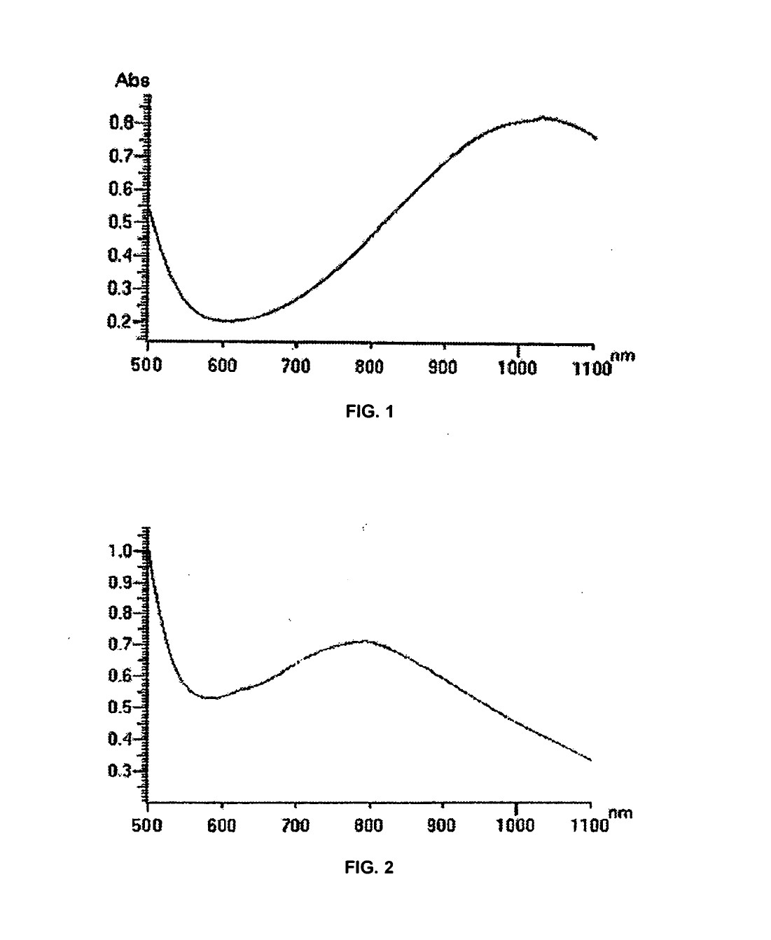

0.2 mmol of monomer 1 and 8% of catalyst Pd (PPh₃)₂Cl₂ were placed in a two-neck round flask, degassed and refilled with N₂ three times, then anhydrous tetrahydrofuran (THF) was added followed by 0.22 mmol of 2,5-bis(tributylstannyl)thiophene. The mixture was heated to reflux to react at 80-85° C. for 24 hrs, then 5% of bromobenzene was added, the mixture was allowed to react at 80° C. for another 24 hrs. After cooling down to room temperature, the reaction mixture was poured into CH₃OH, obtained solid was filtered and recrystallized from CH₂Cl₂/CH₃OH several times and washed with CH₃OH until CH₃OH washing solution became colorless, the dark solid was filtered and dried under vacuum to give Polymer 1 as a black solid. Absorption of Polymer 1 was measured in CH₂Cl₂ and the spectrum is shown in FIG. 1.

### EXAMPLE 2

### Synthesis of Polymer 2

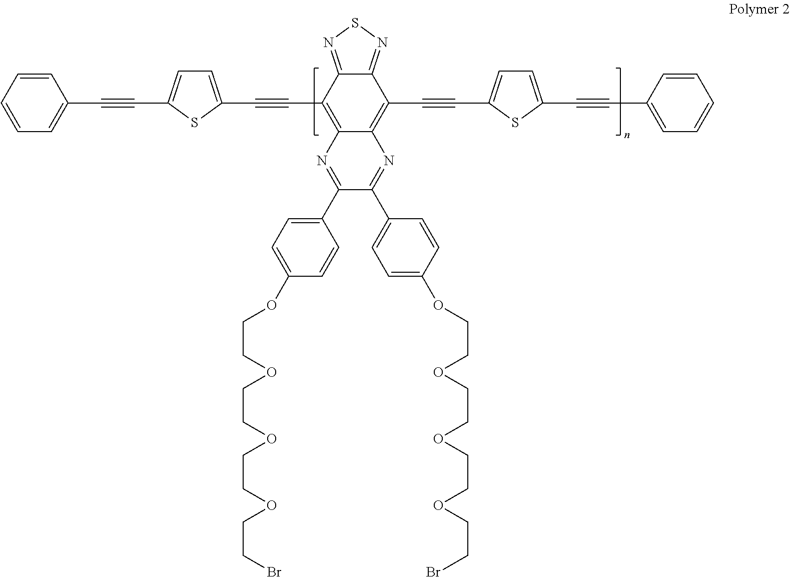

Scheme 5 below shows the co-polymerization of monomer 1 and 2,5-diethynylthiophene to produce Polymer 2.

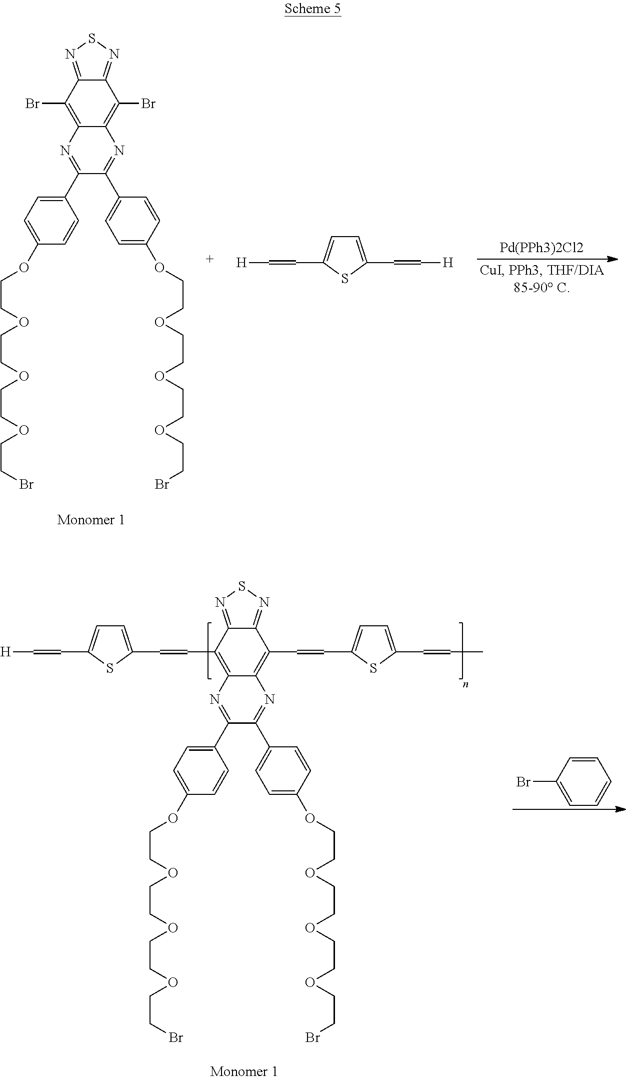

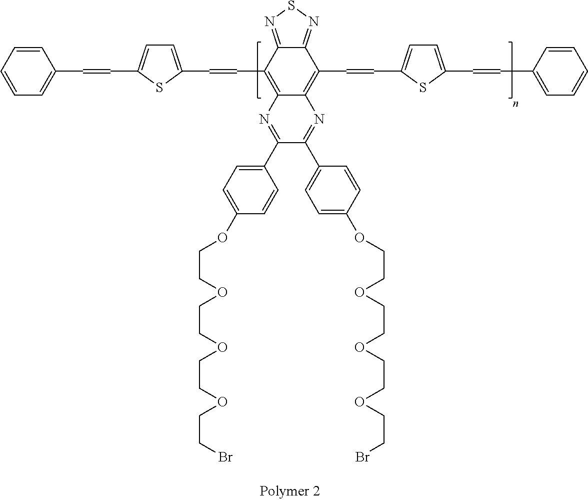

0.2 mmol of monomer 1 and 5% of catalyst Pd (PPh₃)₂Cl₂, 8% of Cu and 15% of PPh3 were placed in a two-neck round flask, degassed and refilled with N₂ three times, then anhydrous THF and diisopropyl alcohol (DIA) were added followed by a solution of 0.22 mmol of 2,5-diethynylthiophene in THF. The mixture was reacted at 80-85° C. for 24 hrs, then 5% of bromobenzene was added, the mixture was allowed to react for another 20 hrs. After cooling down to room temperature, the reaction mixture was poured into CH₃OH, obtained solid was filtered and recrystallized from CH₂Cl₂/CH₃OH and washed with CH₃OH several times, the dark solid was filtered and dried under vacuum to give Polymer 2 as a black powder.

Polymer 1 with absorption at lower wavelength was also synthesized using different ratio of Monomer 1 and 2,5-bis(tributylstannyl)thiophene (monomer 1:2,5-bis(tributylstannyl)thiophene around 1:1.2). The spectrum is shown in FIG. 2.

### EXAMPLE 3

### Synthesis of Network Polymer 1

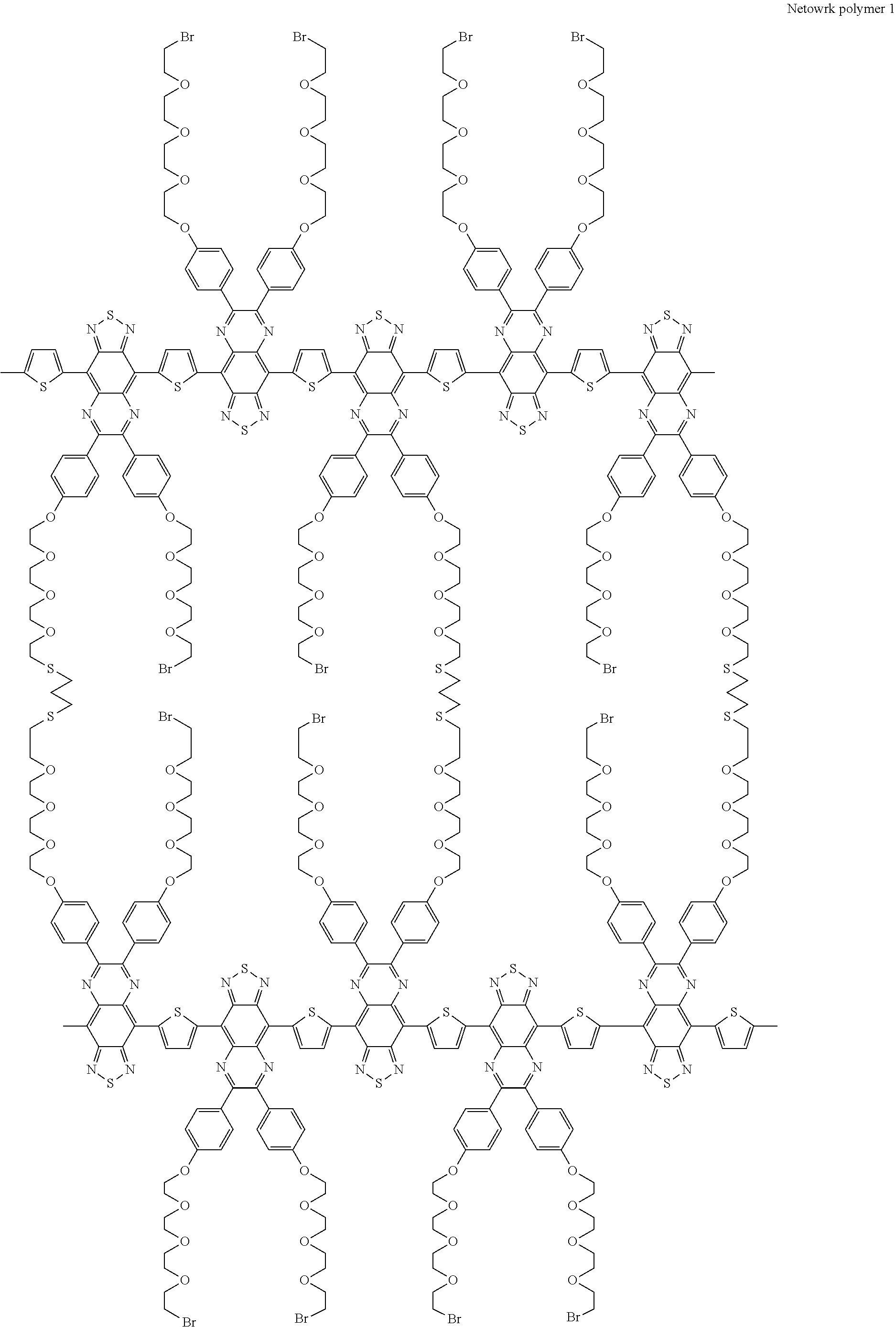

A polymer precursor, the above Polymer 1 with absorption at lower wavelength was used to make the Network Polymer 1. Scheme 6 below illustrates the preparation of Network Polymer 1 using cross linker 1,3-dithiopropane and post-crosslink approach.

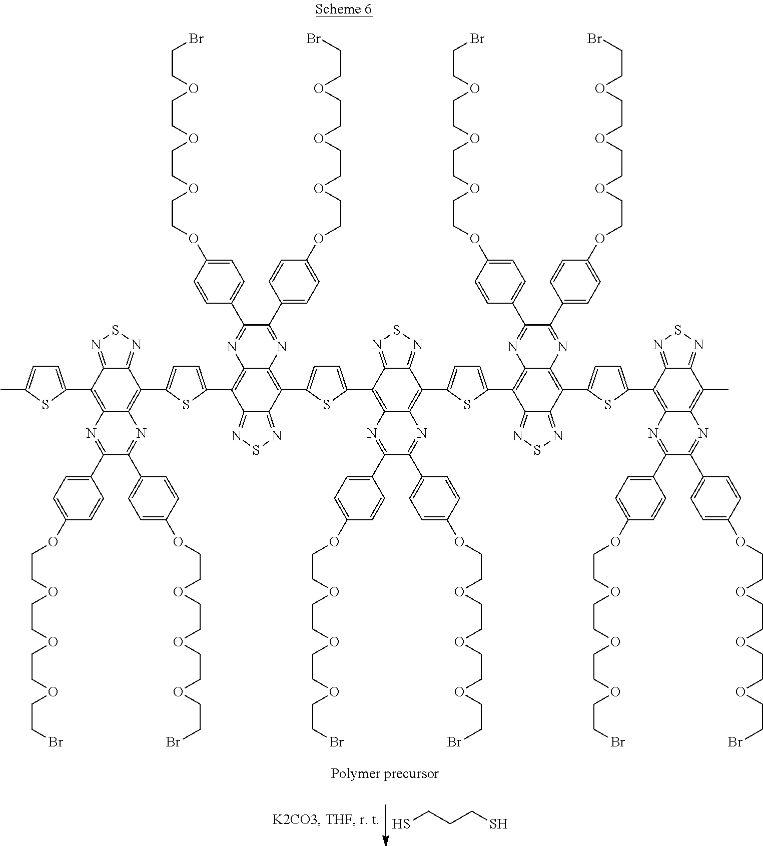 [SMILES: Cc1ccc(-c2c3nsnc3c(-c3ccc(-c4c5nsnc5c(-c5ccc(-c6c7nsnc7c(-c7ccc(-c8c9nsnc9c(-c9ccc(-c%10c%11nsnc%11c(C)c%11nc(-c%12ccc(OCCOCCOCCOCCBr)cc%12)c(-c%12ccc(OCCOCCOCCOCCBr)cc%12)nc%10%11)s9)c9nc(-c%10ccc(OCCOCCOCCOCCBr)cc%10)c(-c%10ccc(OCCOCCOCCOCCBr)cc%10)nc89)s7)c7nc(-c8ccc(OCCOCCOCCOCCBr)cc8)c(-c8ccc(OCCOCCOCCOCCBr)cc8)nc67)s5)c5nc(-c6ccc(OCCOCCOCCOCCBr)cc6)c(-c6ccc(OCCOCCOCCOCCBr)cc6)nc45)s3)c3nc(-c4ccc(OCCOCCOCCOCCBr)cc4)c(-c4ccc(OCCOCCOCCOCCBr)cc4)nc23)s1 ; SCCCS]

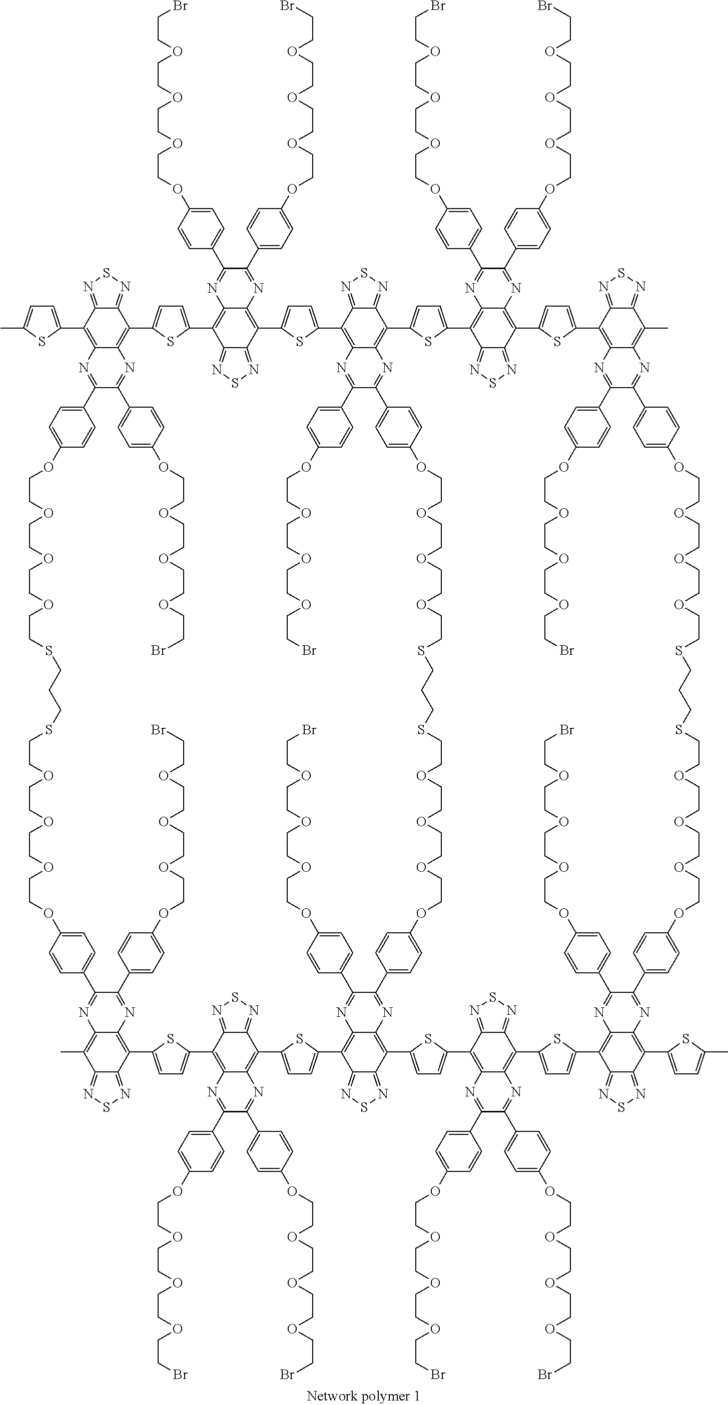

1 mmol of Polymer 1 was dissolved in THF and 4 mmol of K₂CO₃ and 0.5 mmol of 1,3-dithiopropane were added, the mixture was stirred at room temperature for 24 hrs and then poured into water. The precipitate was filtered and washed with water and CH₃OH and then re-crystallized from CH₂Cl₂/CH₃OH. The obtained dark solid was dried by air.

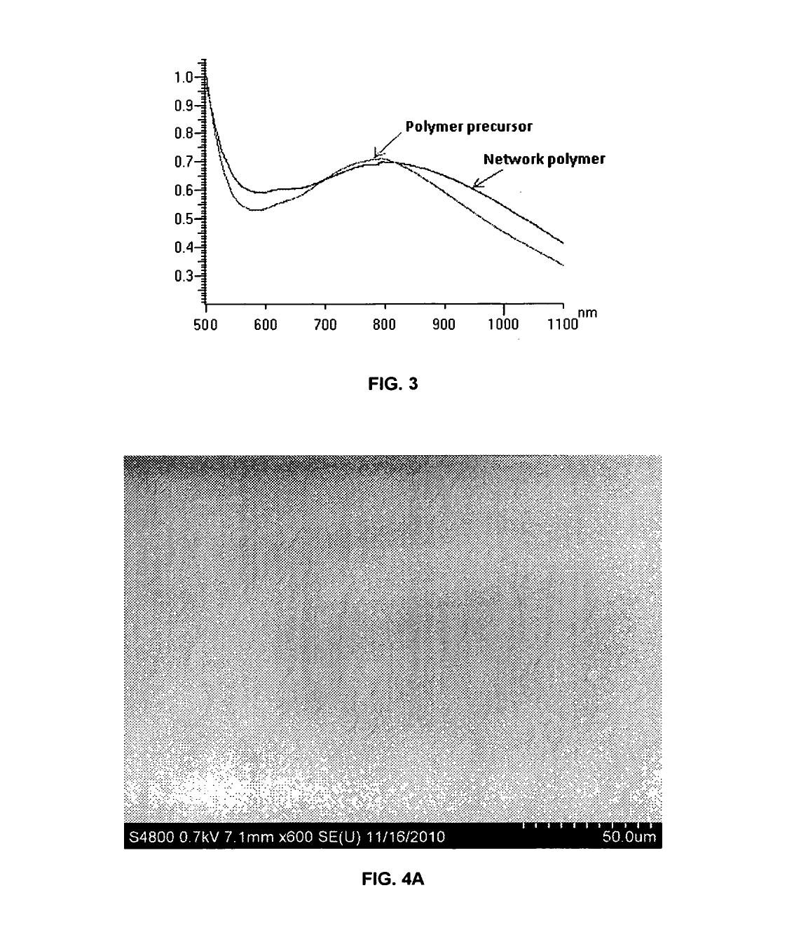

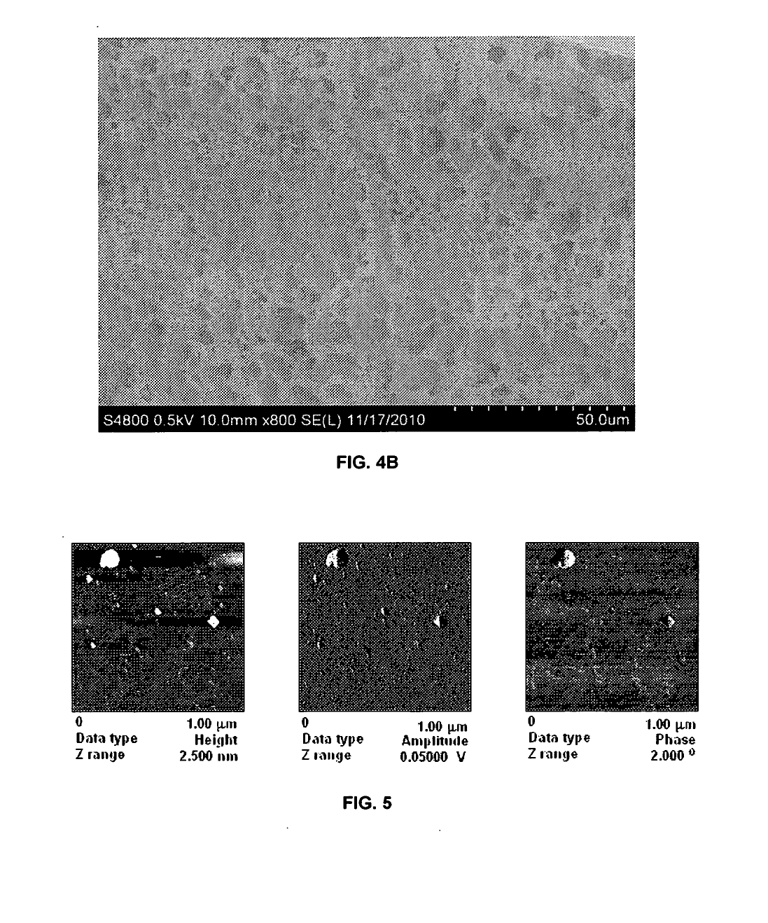

The precursor Polymer 1 has very good solubility in most of the organic solvents. Compared with the polymer precursor, the solubility of the obtained dark solid was decreased but still soluble in most of the organic solvents. FIG. 3 shows the absorption spectra of precursor Polymer 1 and the Network Polymer 1 in CH₂Cl₂ solution. Compared with the polymer precursor, the absorption of the network polymer has a red shift, though the red shift is not large. Without wishing to be bound by any theory, this shift is attributed to the side chains of the polymer and cross-linker not being conjugated. FIG. 4 shows SEM images of precursor Polymer 1 and Network Polymer 1. FIG. 4A shows the SEM image of precursor Polymer 1. FIG. 4B shows the SEM image of Network Polymer 1.

### EXAMPLE 4

### Synthesis of COOH-functionalized Network Polymer 2

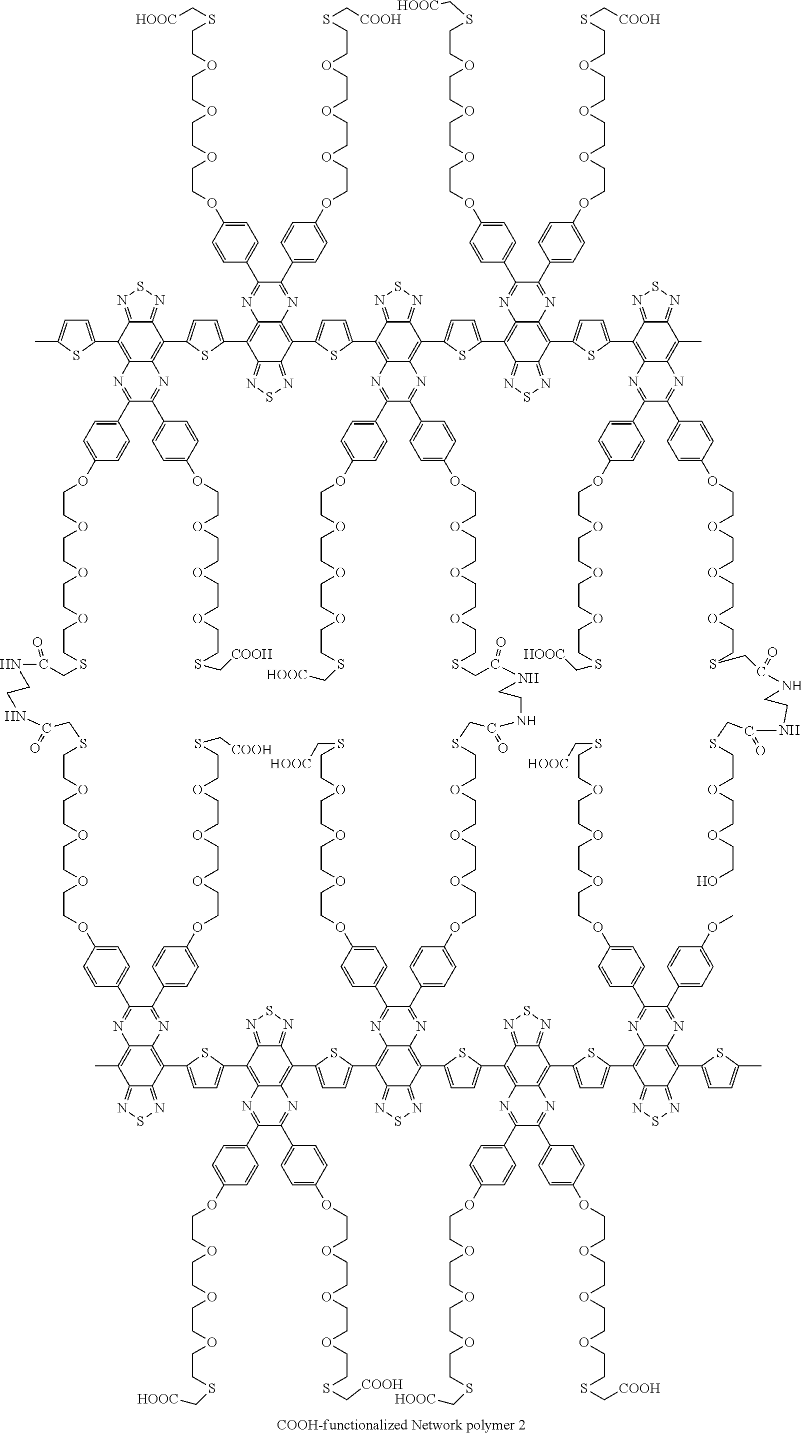

A polymer precursor, the below Polymer 1, was used to make the COOH-Functionalized Network Polymer 2. Scheme 7 below illustrates the preparation of network precursor COOH-Functionalized Polymer 1 from Polymer 1.

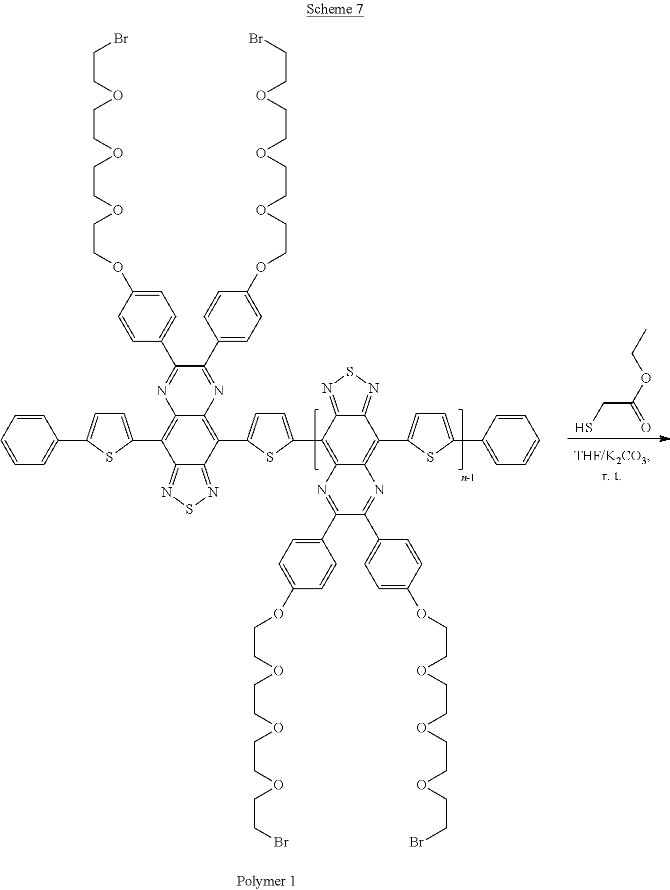

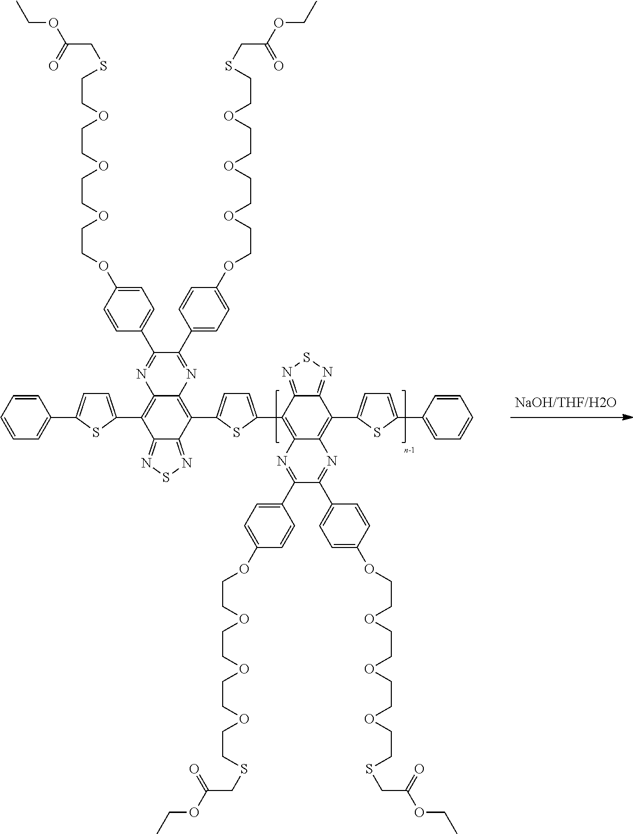

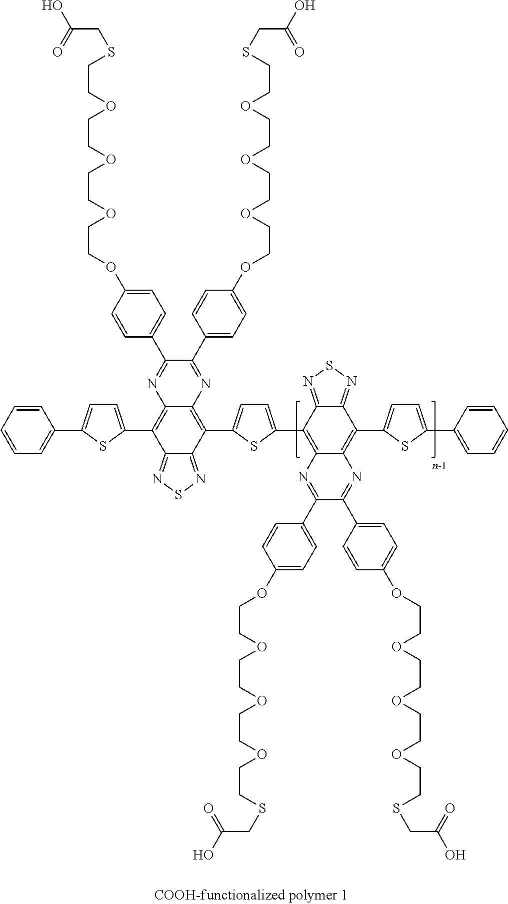

1 mmol of Polymer 1 was reacted with 3.5 mmol of ethyl 2-mercaptoacetate at room temperature in THF in the presence of 4 mmol of K₂CO₃ for 24 hrs. After 24 hrs, the reaction mixture was poured into water and then filtered. The obtained dark solid was washed with water, then several times with CH₃OH to get rid of excess ethyl 2-mercaptoacetate. After washing with CH₃OH, the obtained dark solid was dissolved in THF and 2M of aqueous NaOH solution was added. A few seconds after addition of the NaOH solution, a large amount of precipitate occurred. The precipitate was collected and transferred into a dialysis tube. Dialysis was carried out against water to remove NaOH, THF and other water soluble impurities. After about 30 minutes, all the precipitate was completely dissolved in water in the dialysis tube. After dialysis against water (8 water changes), the solution was transferred into a single-neck round bottom flask and dried by lyophilization to give COOH-functionalized polymer 1 as a dark solid. This COOH-functionalized Polymer 1 has very good water solubility. FIG. 5 shows Atomic Force Microscopy images of COOH-functionalized Polymer 1.

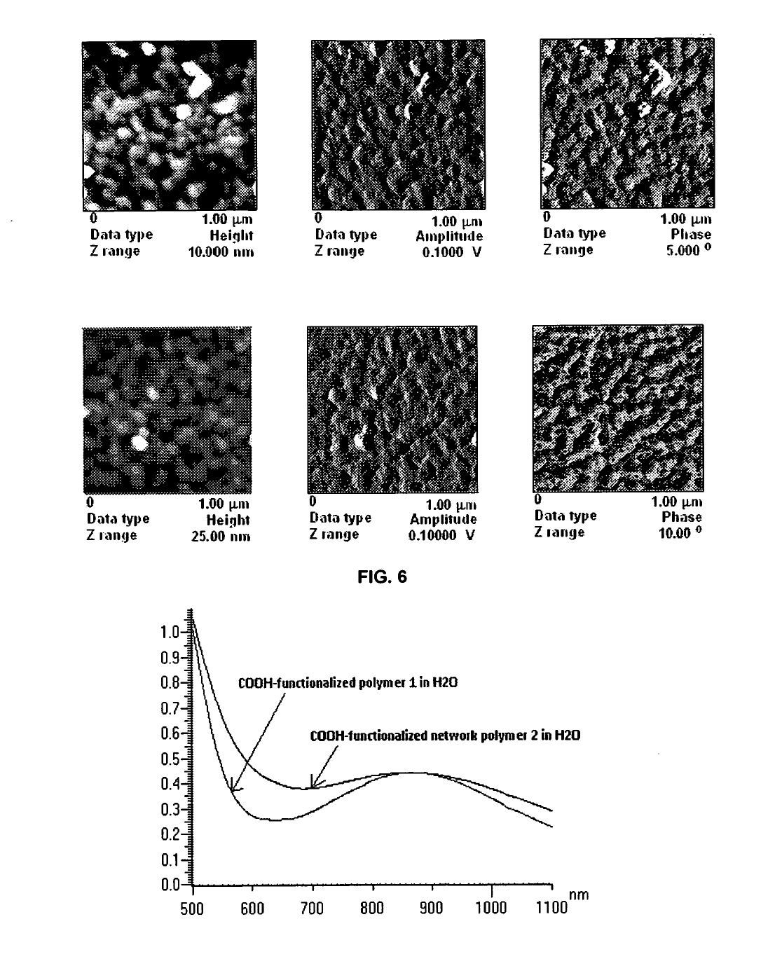

Scheme 8 below illustrates the preparation of COOH-Functionalized Network Polymer 2 from COOH-Functionalized Polymer 1. 20 mg of COOH-Functionalized Polymer 1 was dissolved in 3 mL of 0.1M MES buffer, and 3.8 mg of EDC in 0.2 mL H₂O was added, followed by 8 mg of sulfo-NHS in 0.2 mL H₂O. The mixture was stirred at room temperature for 30 minutes, and 0.5 mg of ethylenediamine was added. The whole mixture was allowed to stir for 12 hours and then transferred into dialysis tube. Dialysis against water (4 water changes) was carried out. After dialysis, the mixture was transferred into a single-neck round bottom flask and dried by lyophilization to give COOH-Functionalized Network Polymer 2 as a dark solid. The dried COOH-Functionalized Network Polymer 2 has good solubility in DMSO. FIG. 6 shows Atomic Force Microscopy images of COOH-functionalized Network Polymer 2. FIG. 7 shows an overlayed absorption spectra of COOH-Functionalized Polymer 1 precursor and COOH-Functionalized Network Polymer 2. As can be seen, both polymers show a similar absorption in the visible and near-IR regions.

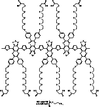

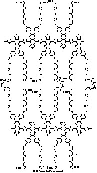

By the post-crosslink approach, polymer networks can be formed while retaining good solubility in most common organic solvents. This solubility leads to ease in the making, handling and processing of the polymer networks. These polymers combine the advantages of the network, easy processability due to good solubility, high charge-carrier mobility and NIR optical property together and can be used as semiconducting materials in organic photovoltaic cells, organic light-emitting diodes, field-effect transistors, organic semiconductors, electronic optical sensors and other opto-electronic devices, and the like. Moreover, each of the polymer precursors themselves also can be used as semiconducting materials in organic photovoltaic cells and related applications.

Any numbers expressing quantities of ingredients, constituents, reaction conditions, and so forth used in the specification are to be understood as being modified in all instances by the term “about”. Notwithstanding that the numeric al ranges and parameters setting forth, the broad scope of the subject matter presented herein are approximations, the numerical values set forth are indicated as precisely as possible. Any numerical value, however, may inherently contain certain errors or inaccuracies as evident from the standard deviation found in their respective measurement techniques. None of the features recited herein should be interpreted as invoking 35 U.S.C. §112, ¶6, unless the term “means” is explicitly used.

Although the present invention has been described in connection with preferred embodiments thereof, it will be appreciated by those skilled in the art that additions, deletions, modifications, and substitutions not specifically described may be made without departing from the spirit and scope of the invention.

1. A polymeric precursor material comprising: a copolymer of:
a first monomer (1), (2), (3) (4), (5), (6), (7), (8), (9), (10), (11), (12), (13), (14) or (15), and
a second monomer (16), (17), (18), (19), (20), (21), (22), (23), (24), (25), (26) or (27),
wherein: 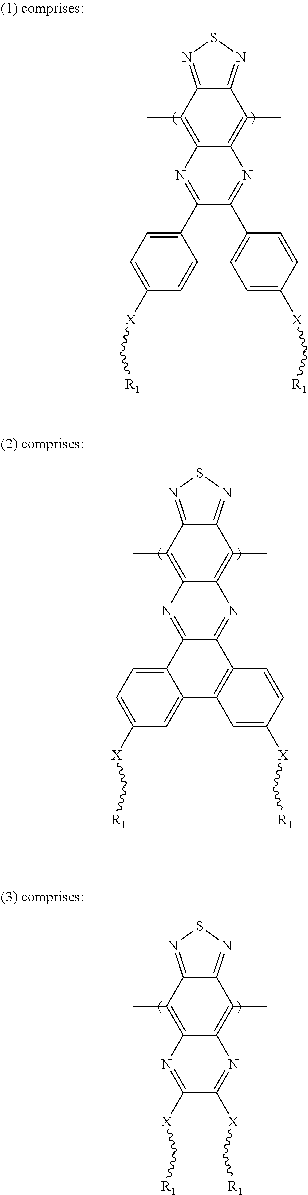 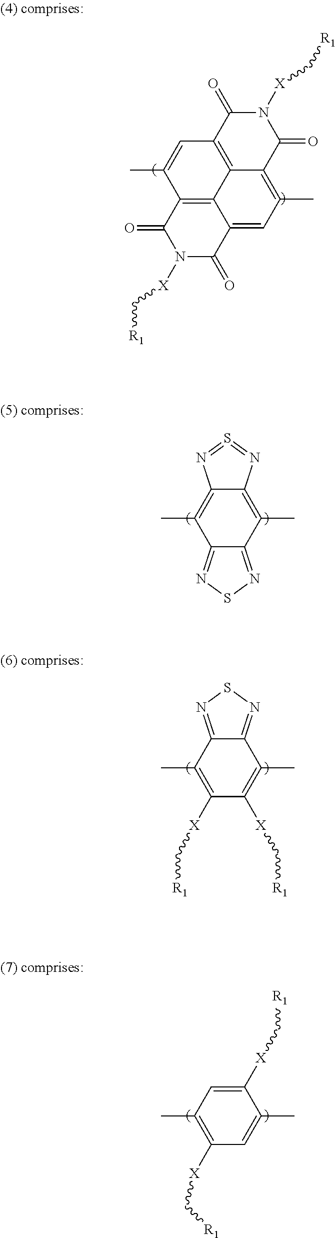 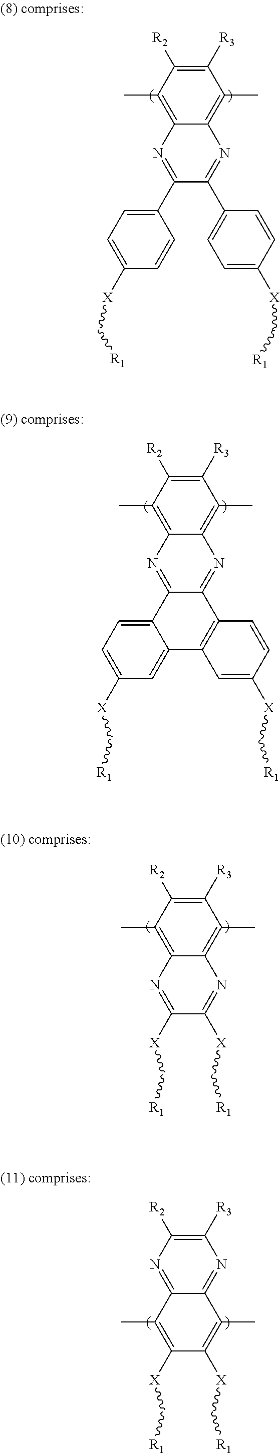 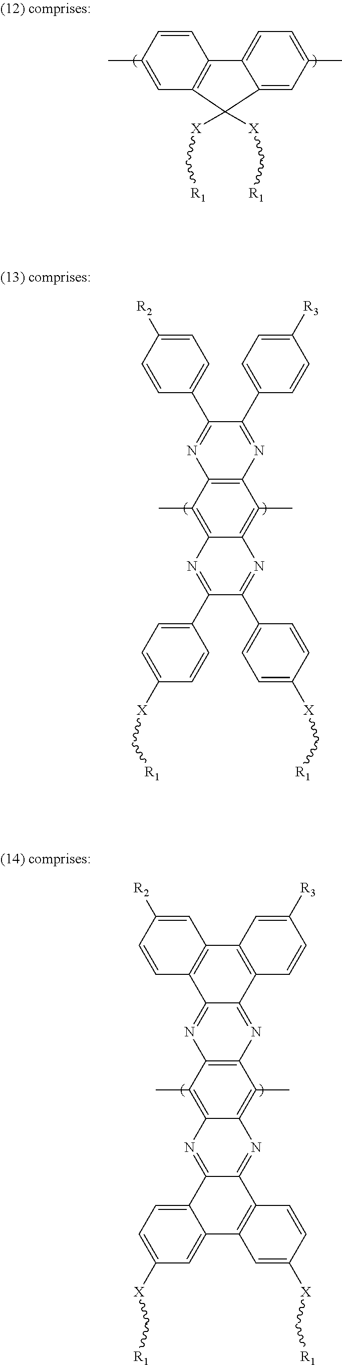 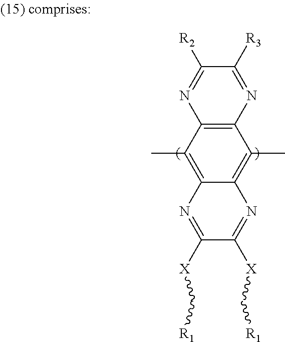
wherein
X=H, C, O, N, S, P, Si, or B or; [symbol]
=H, an oligo- or poly-ethylene glycol, an alkyl chain with or without branches, or an optionally substituted conjugated chain;
R₂ and R₃=H or X [symbol] R₁;
R₁=H, alkyl, alkene, alkyne, OH, Br, Cl, I, F, SH, COOH, NH₂, NR₃, azide, SO₃Na, CHO, maleimide, or HNS ester; or any heterocyclic compounds that can form a metal complex or nano-particle or other applicable functional group, such as a carbohydrate, a protein, DNA, an antibody, an antigen, an enzyme or a bacteria, and wherein: 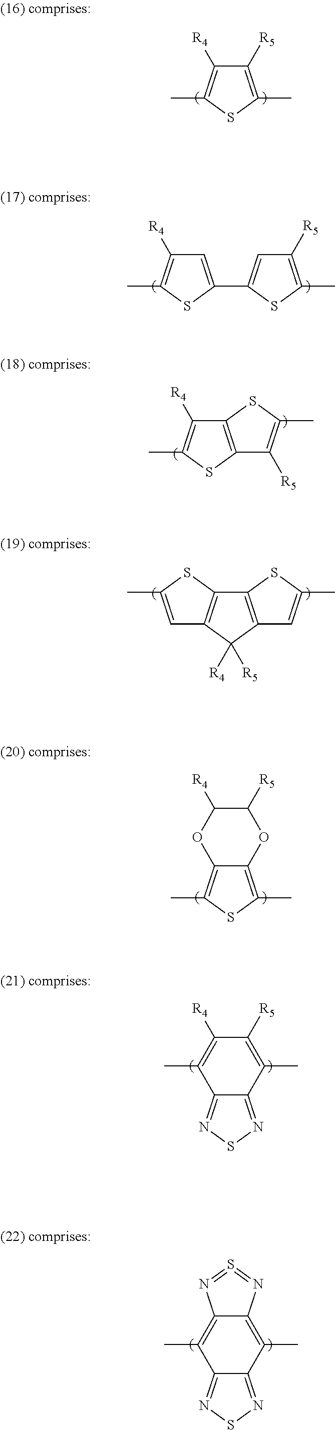 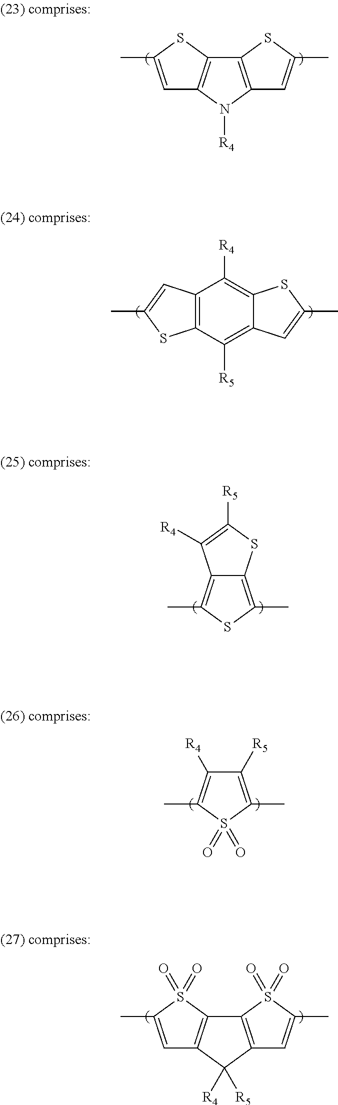
wherein:
X=C, O, CO, N, S, P, Si, or B; [symbol]
=an oligo- or poly-ethylene glycol, an alkyl chain with or without branches, or an optionally substituted conjugated chain;
R₄ and R₅=H or X [symbol] R₁′
R₁=H, alkyl, alkene, alkyne, OH, Br, Cl, I, F, SH, COOH, NH₂, NR₃, azide, SO₃Na, CHO, maleimide, or HNS ester, or any heterocyclic compounds that can form a metal complex or nano-particle or other applicable functional group, such as a carbohydrate, a protein, DNA, an antibody, an antigen, an enzyme or a bacteria.

2. The polymeric precursor material of claim 1, further comprising a third monomer (39), (40), (41), (42), (43), (44), (45), (46), (47), (48) (49), (50), (51), (52), (53) or (54) wherein: 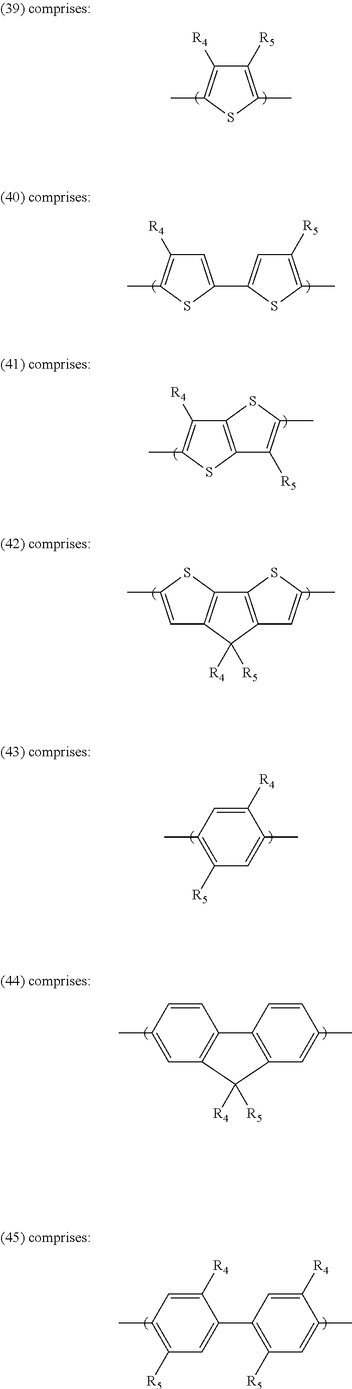 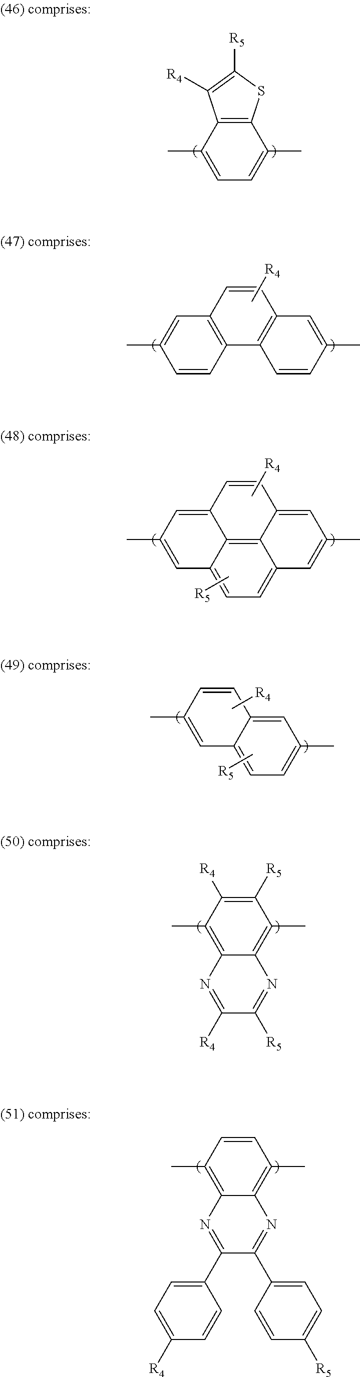 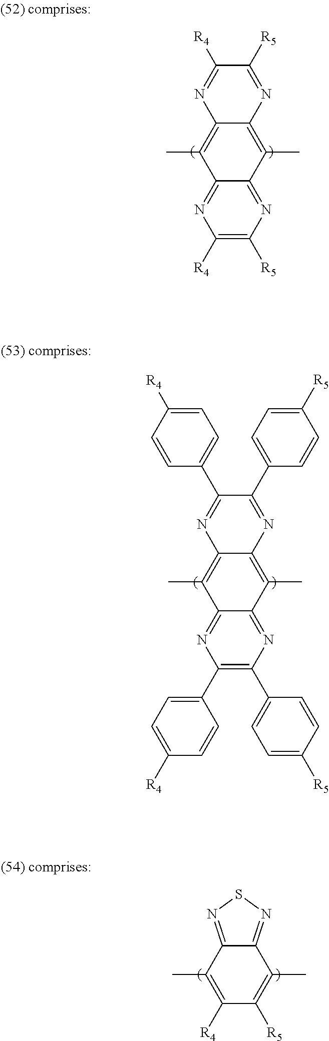
wherein:
X=C, O, CO, N, S, P, Si, or B; [symbol]
=oligo- or poly-ethylene glycol, alkyl chain with or without branches, or an optionally substituted conjugated chain;
R₄ and R₅=H or X [symbol] R₁;
R₁=H, alkyl, alkene, alkyne, OH, Br, Cl, I, F, SH, COON, NH₂, NR₃, azide, SO₃Na, CHO, maleimide, or FINIS ester, or any heterocyclic compounds that can form a metal complex or nano-particle or other applicable functional group, such as a carbohydrate, a protein, DNA, an antibody, an antigen, an enzyme or a bacteria.

3. A polymeric precursor material comprising: a copolymer of:
a first monomer (28), (29), (30) (31), (32), (33), (34), (35), (36), (37) or (38); and
a second monomer (39), (40), (41), (42), (43), (44), (45), (46), (47), (48) (49), (50), (51), (52, (53) or (54);
wherein: 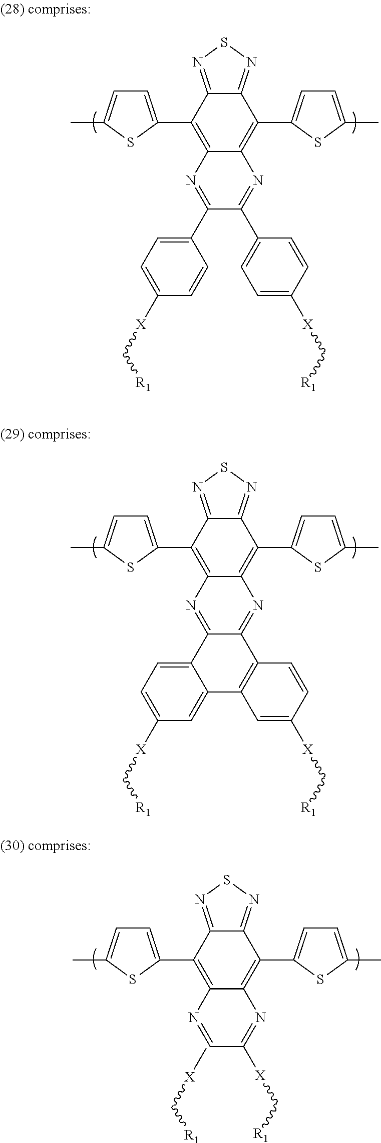 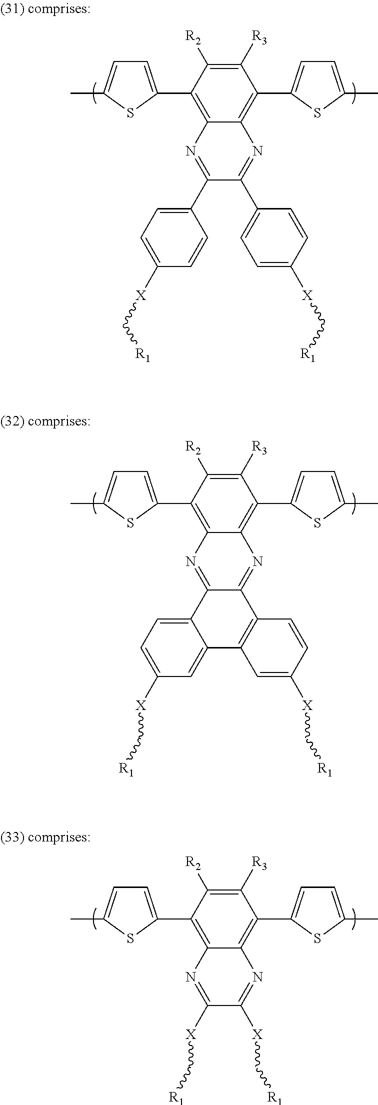 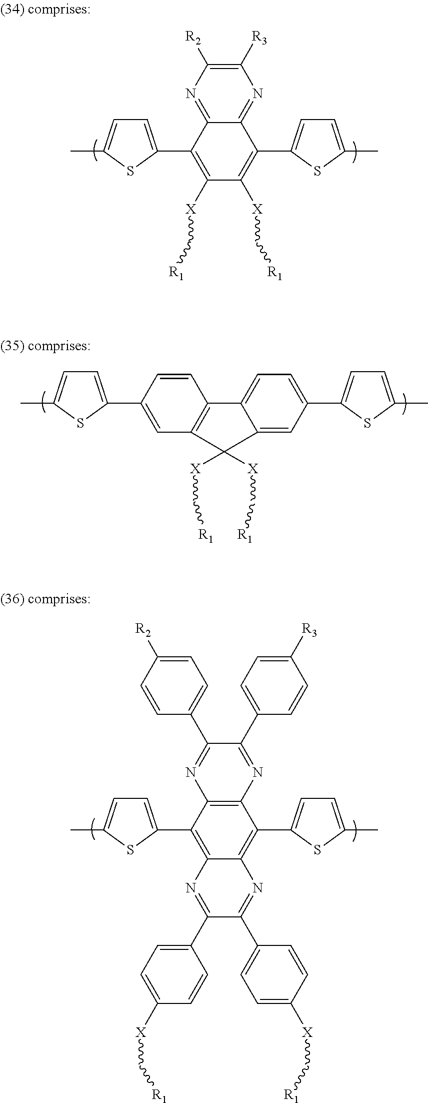 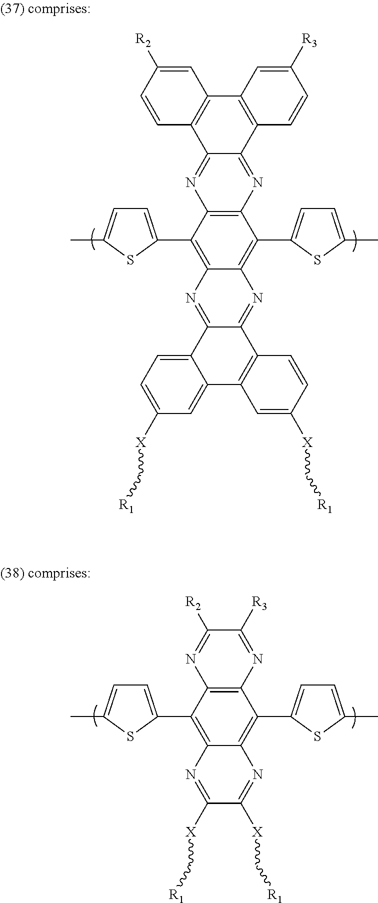
wherein:
X=H, C, O, N, S, P, Si, or; [symbol]
=H, oligo- or poly-ethylene glycol, alkyl chain with or without branches, or an optionally substituted conjugated chain;
R₂ and R₃=H or X [symbol] R₁;
R₁=H, alkyl, alkene, alkyne, OH, Br, Cl, I, F, SH, COOH, NH₂, NR₃, azide, SO₃Na, CHO, maleimide, or HNS ester; or any heterocyclic compounds that can form a metal complex or nano-particle or other applicable functional group, such as a carbohydrate, a protein, DNA, an antibody, an antigen, an enzyme or a bacteria;
wherein: 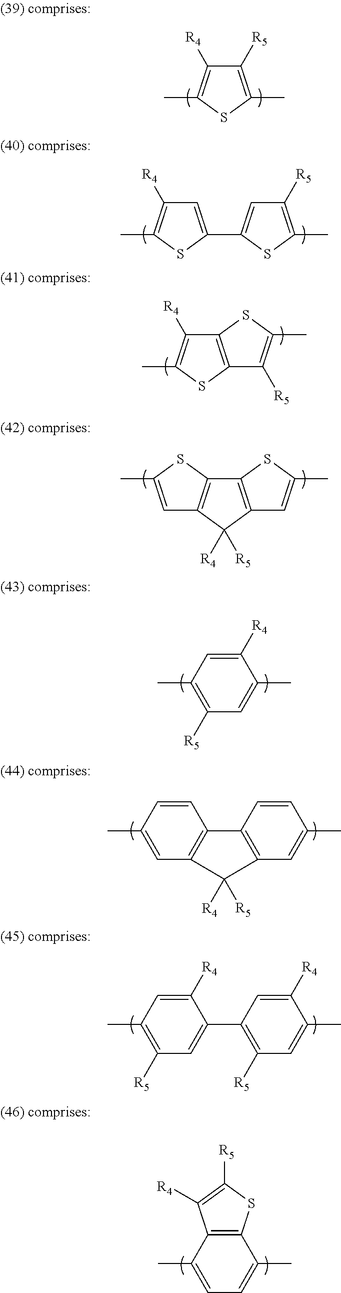 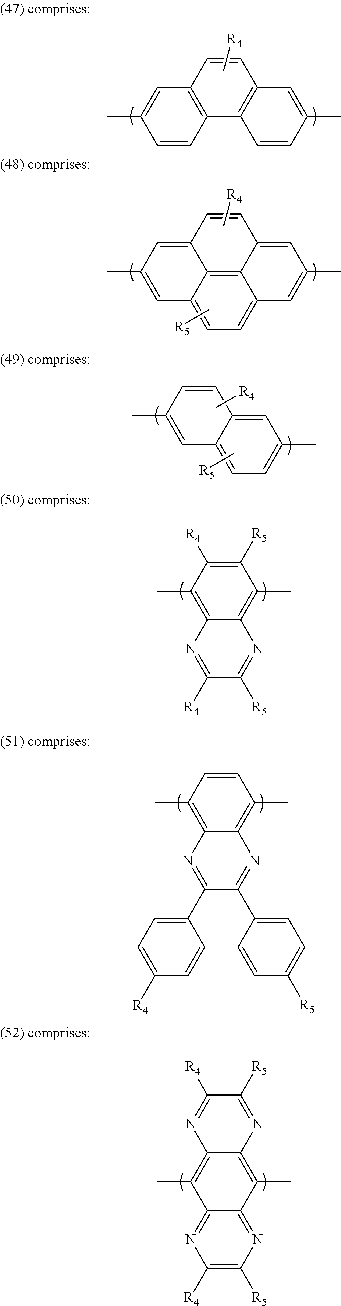 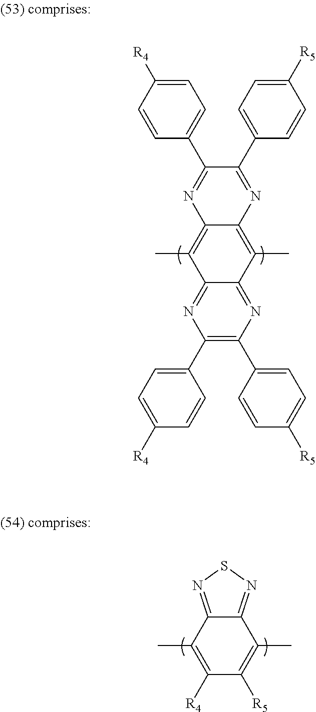
wherein:
X=C, O, CO, N, S, P, Si, or B; [symbol]
=oligo- or poly-ethylene glycol, alkyl chain with or without branches, or an optionally substituted conjugated chain;
R₄ and R₅=H or X [symbol] R₁;
R₁=H, alkyl, alkene, alkyne, OH, Br, Cl, I, F, SH, COOH, NH₂, NR₃, azide, SO₃Na, CHO, maleimide, or HNS ester, or any heterocyclic compounds that can form a metal complex or nano-particle or other applicable functional group, such as a carbohydrate, a protein, DNA, an antibody, an antigen, an enzyme or a bacteria.

4. The polymeric precursor material of claim 3, further comprising a third monomer (16), (17), (18), (19), (20), (21), (22), (23), (24), (25), (26) or (27), wherein: 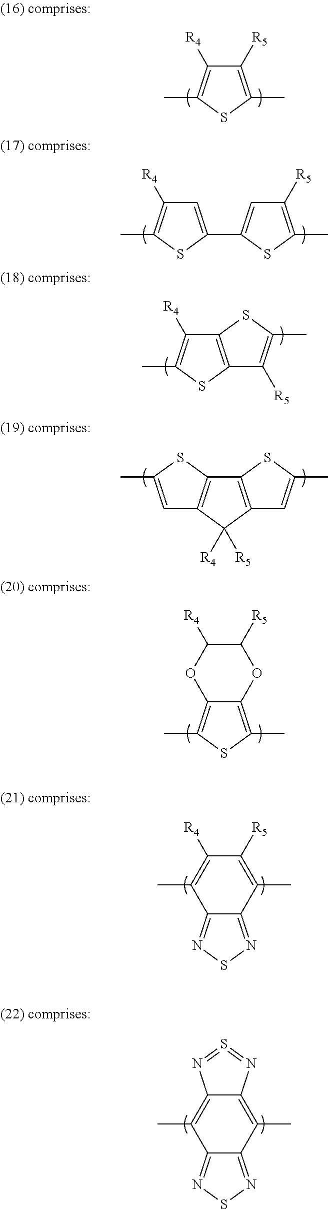 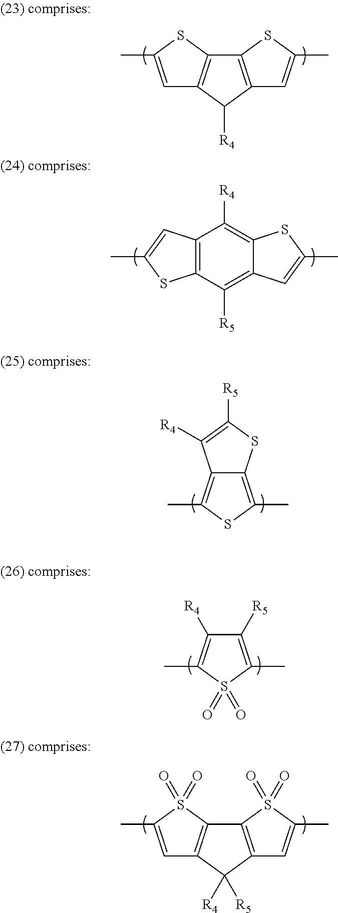
wherein:
X=C, O, CO, N, S, P, Si, or B; [symbol]
=oligo- or poly-ethylene glycol, alkyl chain with or without branches, or an optionally substituted conjugated chain;
R₄ and R₅=H or X [symbol] R₁;
R₁=H, alkyl, alkene, alkyne, OH, Br, Cl, I, F, SH, CO H, NH₂, NR₃, azide, SO₃Na, CHO, maleimide, or HNS ester, or any heterocyclic compounds that can form a metal complex or nano-particle or other applicable functional group, such as a carbohydrate, a protein, DNA, an antibody, an antigen, an enzyme or a bacteria.

5. The polymeric precursor material of claim 1,
wherein the second monomer comprises (39), (40), (41), (42), (43), (44), (45), (46), (47), (48), (49), (50), (51), (52), (53) or (54), and
wherein 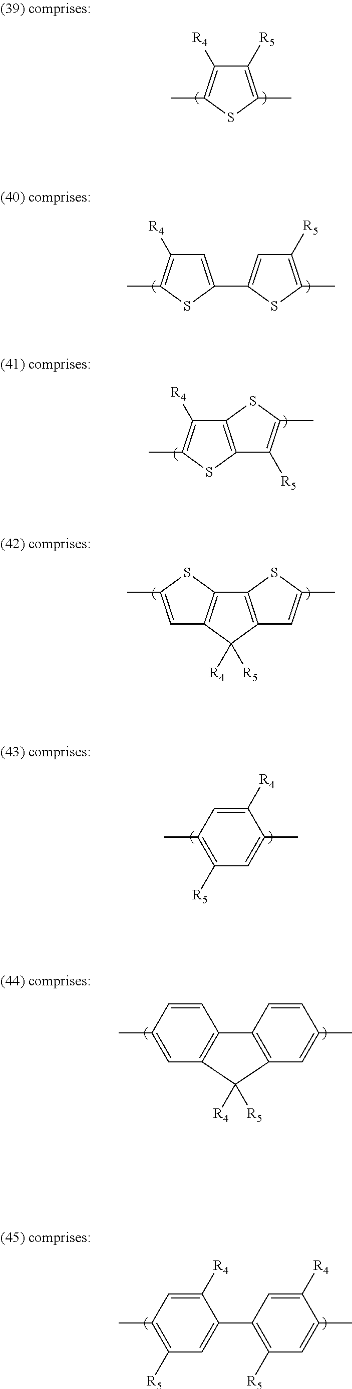 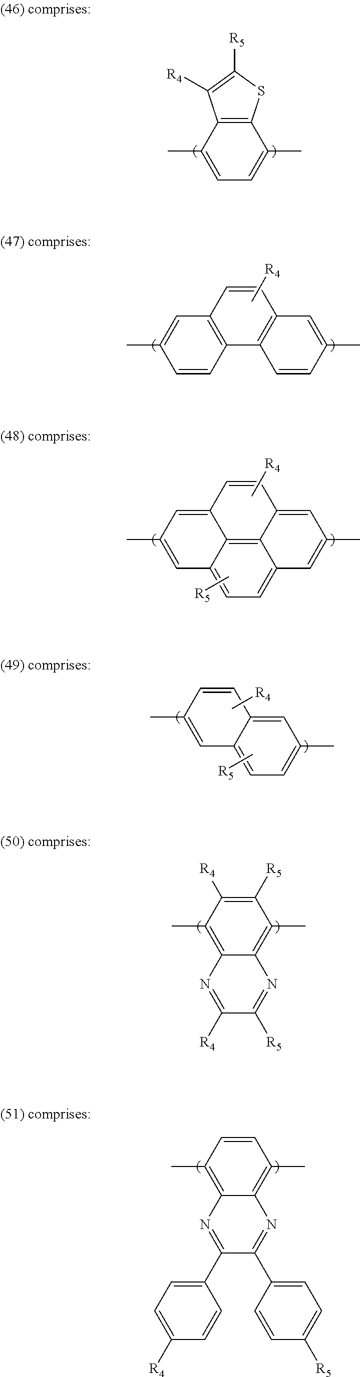 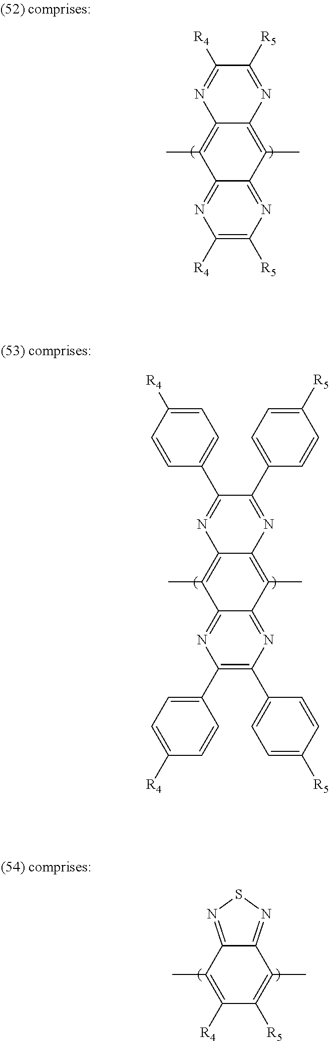
wherein:
X=C, O, CO, N, S, P, Si, or B; [symbol]
=oligo- or poly-ethylene glycol, alkyl chain with or without branches, or an optionally substituted conjugated chain;
R₄ and R₅=H or X [symbol] R₁;
R₁=H, alkyl, alkene, alkyne, OH, Br, Cl, I, F, SH, COOH, NH₂, NR₃, azide, SO₃Na, CHO, maleimide, or HNS ester, or any heterocyclic compounds that can form a metal complex or nano-particle or other applicable functional group, such as a carbohydrate, a protein, DNA, an antibody, an antigen, an enzyme or a bacteria.

6. The polymeric precursor material of claim 3,
wherein the second monomer comprises (16), (17), (18), (19), (20), (21), (22), (23), (24), (25), (26) or (27),
and wherein: 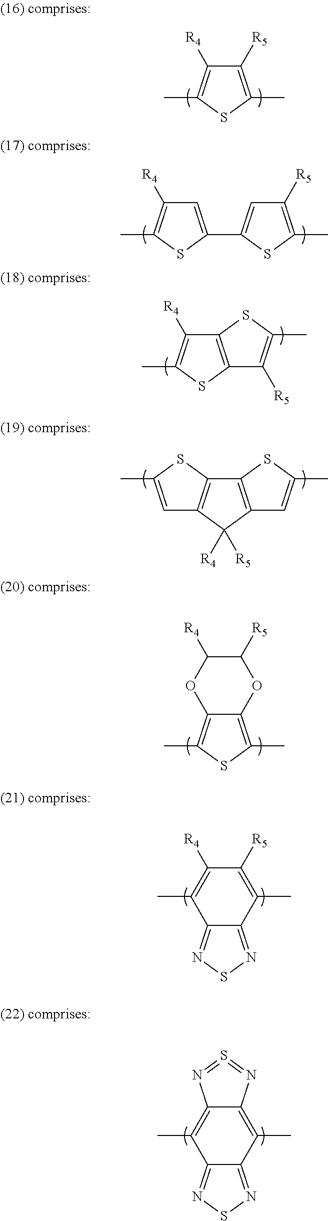 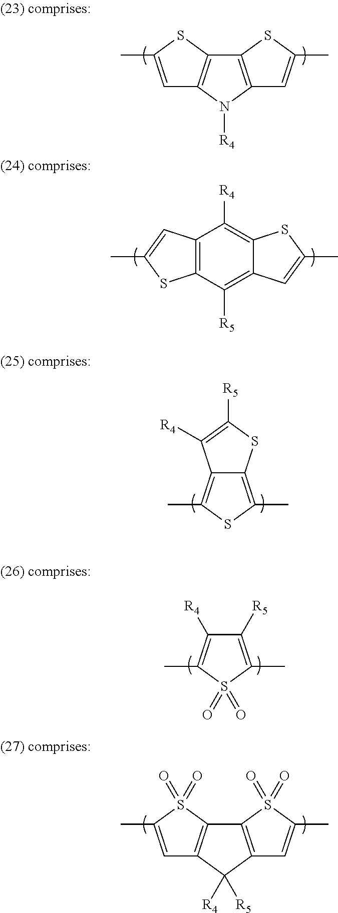
wherein:
X=C, O, CO N S, P, Si, or B; [symbol]
=oligo- or poly-ethylene glycol, alkyl chain with or without branches, or an optionally substituted conjugated chain;
R₄ and R₅=H or X [symbol] R₁;
R₁=H, alkyl, alkene, alkyne, OH, Br, Cl, I, F, SH, COOH, NH₂, NR₃, azide, SO₃Na, CHO, maleimide, or HNS ester, or any heterocyclic compounds that can form a metal complex or nanoparticle or other applicable functional group, such as a carbohydrate, a protein, DNA, an antibody, an antigen, an enzyme or a bacteria.

7. A polymeric material comprising a self-polymerized product of one of the monomers (1)-(54), wherein:

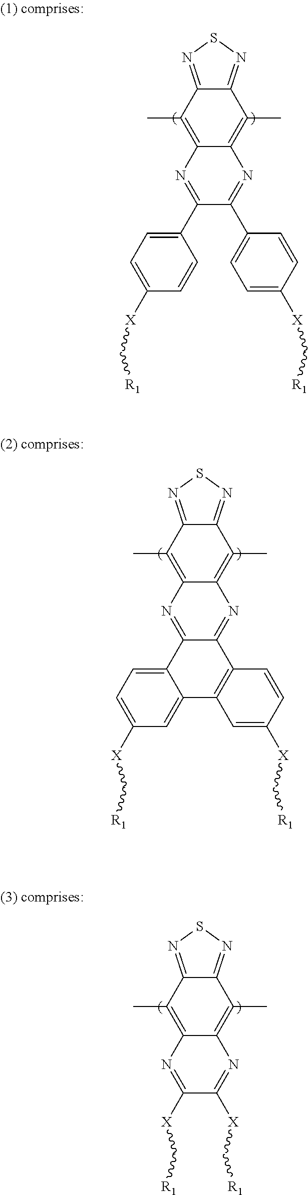

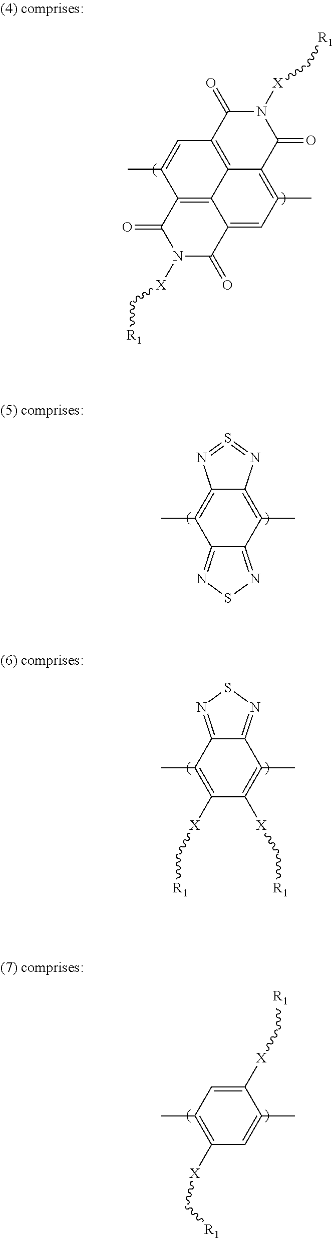

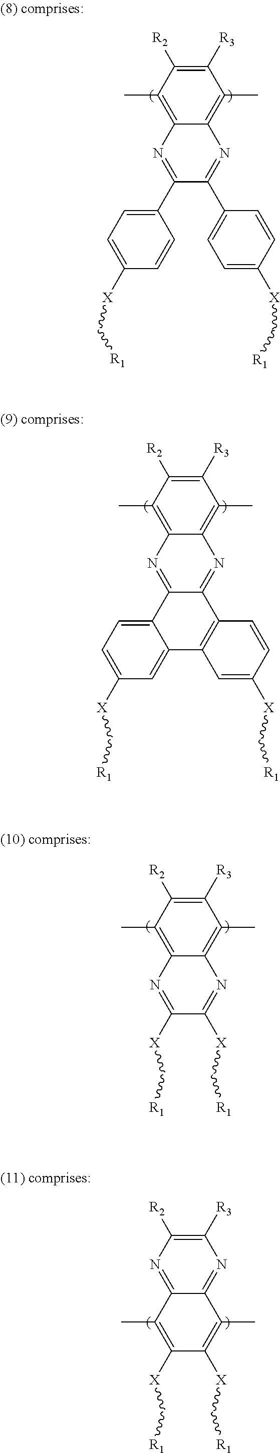

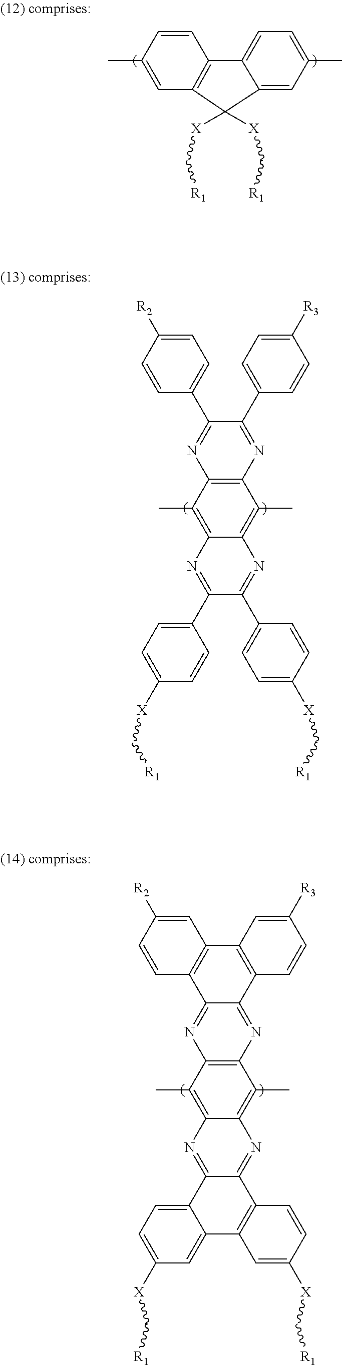

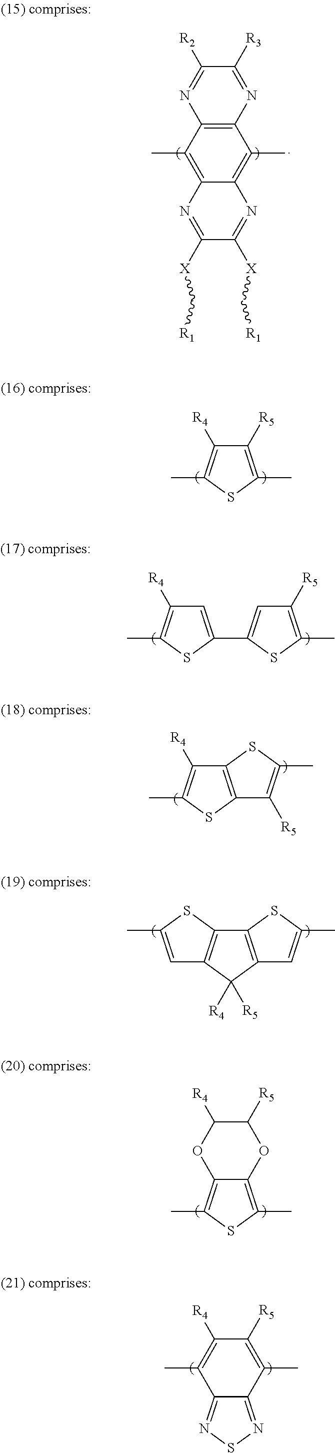

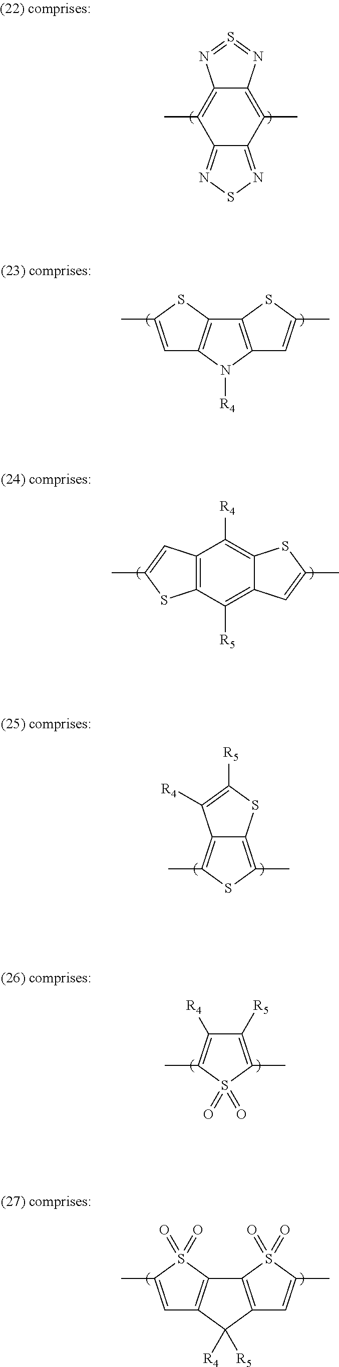

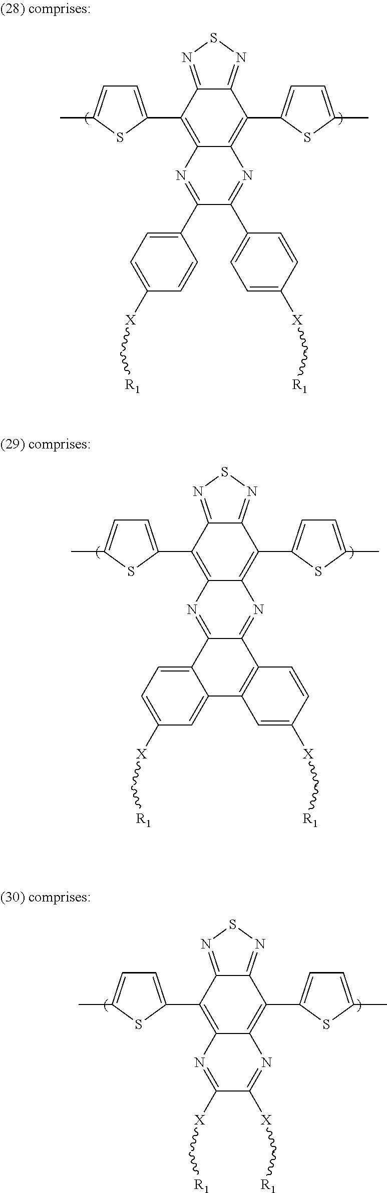

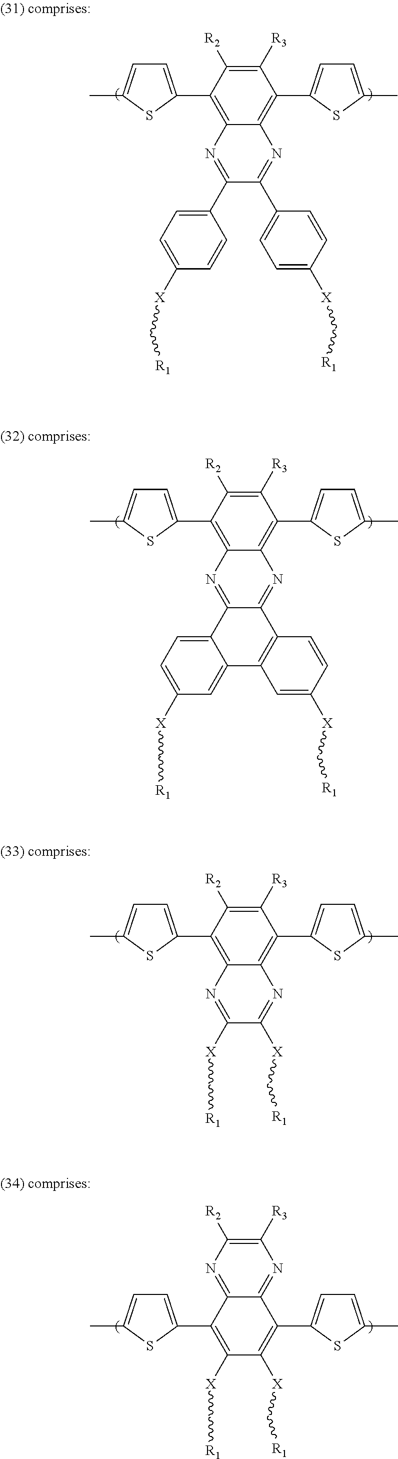

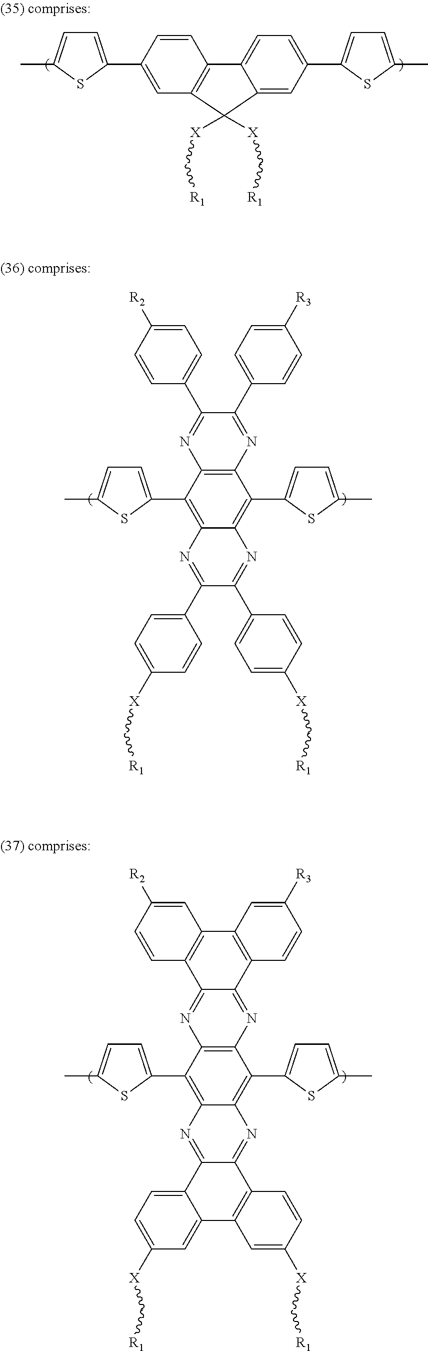

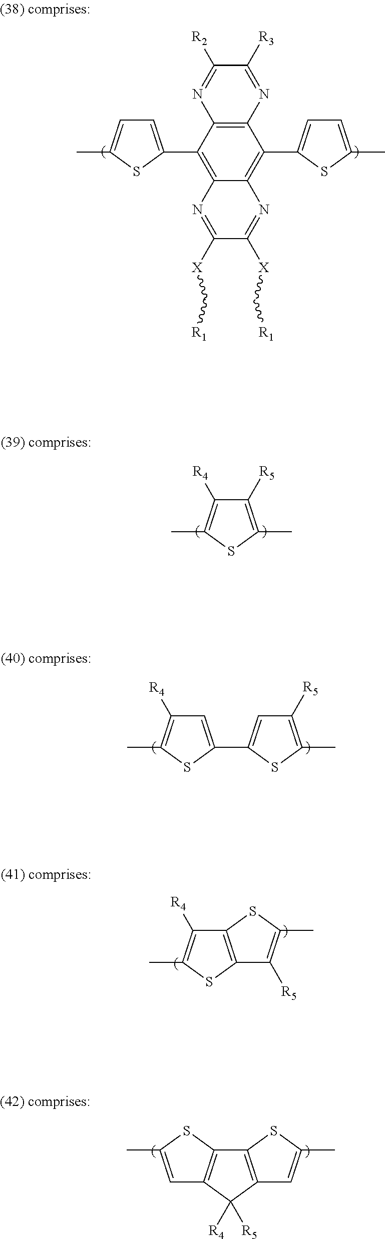

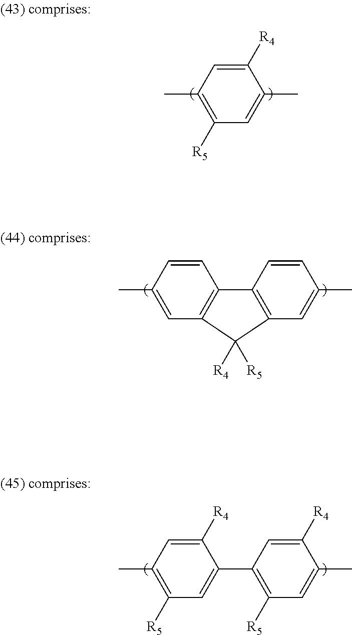

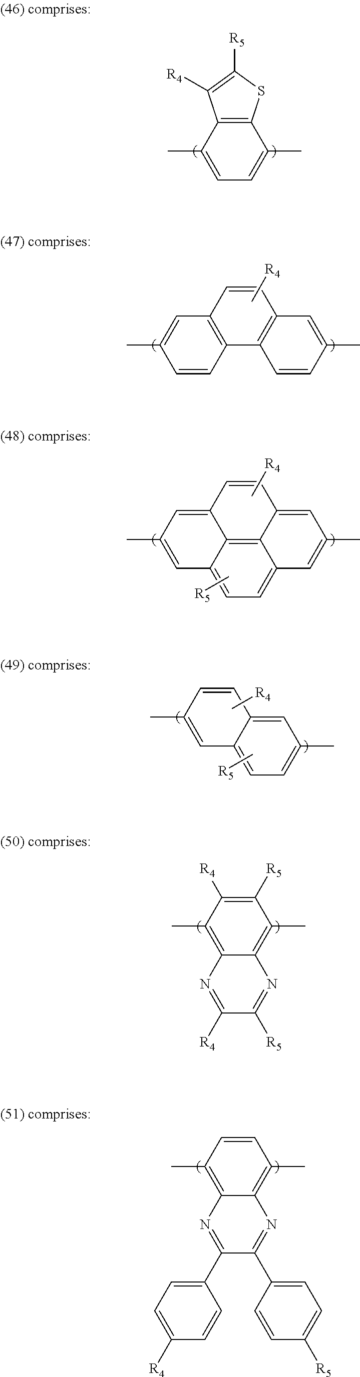

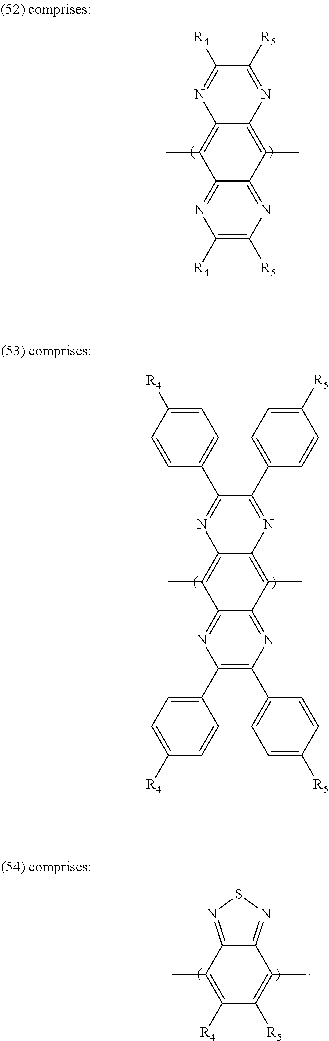

8. The polymeric material of any of claims 1-7, further comprising at least one functional group.

9. The polymeric material of claim 8, wherein the at least one functional group comprises one or more of a carbohydrate, a protein, DNA, an antibody, an antigen, an enzyme or a bacteria.

10. A polymer comprising the polymeric precursor material of any of claims 1-9 in combination with a cross-linking agent.

11. The polymer of claim 10, wherein the cross-linking agent comprises at least one of: a substituted and/or un-substituted aryl group comprising at least one functional group R, a substituted and/or un-substituted heterocyclic group comprising at least one functional group R, a C₁₋₁₅ alkyl, alkene or alkyne comprising at least one functional group R, a metal complex, a nano-particle, or derivatives thereof, or a biomolecule.

12. The polymer of claim 11, wherein the biomolecule comprises a carbohydrate, a protein, DNA, an antibody, an antigen, an enzyme or bacteria.

13. The polymer of claim 11, wherein R comprises, SH, NH₂, COOH, Br, Cl, I, F, OH, CHO, maleimide, NHS ester, azide, alkene, alkyne, metal complex, or nano-particle.

14. The polymer of claim 11, wherein the alkyl, alkene, or alkyne chain optionally comprises at least one branched side chain.

15. A method of making a polymer comprising:
1) preparing a solution comprising the polymeric precursor material of any of claims 1-7; and
2) adding into the solution at least one cross-linking agent.

16. A polymeric material comprising at least one of: 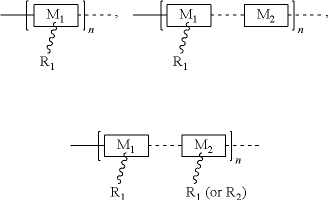
wherein:
M₁ is a substituted or unsubstituted conjugated monomer, a conjugated block oligomer, an alkene or an alkyne;
M₂ is a substituted or unsubstituted monomer, a conjugated block oligomer, an alkene, or an alkyne, each with or without side chains; [symbol]
is an oligo- or poly-ethylene glycol, an alkyl chain with or without branching or an optionally substituted conjugated chain; [symbol]
is a single bond, a double bond or a triple bond;
n is an integer greater than 1; and
R₁ and R₂, which are the same or different, and comprise H, CH₃, alkene, alkyne, OH, Br, Cl, I, F, SH, COOH, NH₂, NR₃, azide, SO₃Na, CHO, maleimide, NHS ester or any heterocyclic compounds that can form a metal complex or nano particle or other applicable functional group, such as a carbohydrate, a protein, DNA, an antibody, an antigen, an enzyme or a bacteria;
and wherein:
M₁ and M₂ comprises zero, one or more than one side chain [symbol] .
